(19) United States
(12) Patent Application Publication
(10) Pub. No.: US 2025/0234725 A1
(43) Pub. Date: Jul. 17, 2025

(54) Display Substrate and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Wenzhe CAI, Beijing (CN); Cong FAN, Beijing (CN); Tingliang LIU, Beijing (CN); Kemeng TONG, Beijing (CN); Fan HE, Beijing (CN); Hui GUAN, Beijing (CN); Hanchao LI, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/701,945

(22) PCT Filed: Mar. 28, 2023
(86) PCT No.: PCT/CN2023/084492

§ 371 Date: Apr. 17, 2024

(51) Int. Cl. H10K 59/131

(52) U.S. Cl. CPC H10K 59/131

(57) ABSTRACT

Disclosed are a display Substrate and a display apparatus. The display substrate includes a display region (AA) and a bezel region (BB) located around the display region (AA), wherein the display region (AA) includes at least one corner region, the bezel region (BB) includes at least one corner region, the at least one corner region of the display region (AA) corresponds to the at least one corner region of the bezel region (BB); a power supply auxiliary line (L11) located in at least one corner region of the bezel region (BB) and arranged to be electrically connected with a first power supply line (VSS); a plurality of power supply connection lines (L12), at least a portion of the power supply connection lines (L12) are arranged to be electrically connected with the power supply auxiliary line (L11).

### CROSS-REFERENCE TO RELATED APPLICATION

The present application is a U.S. National Phase Entry of International Application No. PCT/CN2023/084492 having an international filing date of Mar. 28, 2023. The above-identified application is hereby incorporated by reference.

### TECHNICAL FIELD

The present disclosure relates to, but is not limited to, the field of display technologies, and particularly to a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, extremely high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. This summary is not intended to limit the protection scope of claims.

In a first aspect, an embodiment of the present disclosure provides a display substrate including: a display region and a bezel region located around the display region, wherein the display region includes at least one corner region, the bezel region includes at least one corner region, and the at least one corner region of the display region corresponds to the at least one corner region of the bezel region; A power supply auxiliary line located in at least one corner region of the bezel region and arranged to be electrically connected with a first power supply line; A plurality of power supply connection lines, at least a portion of which are arranged to be electrically connected with the power supply auxiliary line, and extend from a corner region of the bezel region where the power supply auxiliary line is located to a corresponding corner region of the display region.

In an exemplary embodiment, the plurality of power supply connection lines includes a plurality of first power supply connection lines and a plurality of second power supply connection lines, an extension direction of the plurality of first power supply connection lines intersects an extension direction of the plurality of second power supply connection lines, and at least a portion of the first power supply connection lines are electrically connected with at least a portion of the second power supply connection lines.

In an exemplary embodiment, the at least a portion of the first power supply connection lines are located in at least one corner region of the bezel region and extend along a first direction; The at least a portion of the second power supply connection lines extend along a second direction and extend from at least one corner region of the bezel region where the power supply auxiliary line is located to at least one corresponding corner region of the display region; The power supply auxiliary line is respectively electrically connected with the at least a portion of the first power supply connection lines and the at least a portion of the second power supply connection lines, and the power supply auxiliary line, at least a portion of the first power supply line and at least a portion of a second power supply line form a mesh structure in at least one corner region of the bezel region where the power supply auxiliary line is located.

In an exemplary embodiment, a width of the power supply auxiliary line gradually decreases from an end connected to the first power supply line to an end away from the first power supply line.

In an exemplary embodiment, in a direction perpendicular to a plane where the display substrate is located, the display substrate includes a base substrate and a first conductive layer, a second conductive layer, a first source-drain metal layer and a second source-drain metal layer stacked on the base substrate sequentially; the power supply auxiliary line, the first power supply line, the plurality of first power supply connection lines and the plurality of second power supply connection lines are located in the second source-drain metal layer, and the first power supply line is located at a side of the power supply auxiliary line away from the display region.

In an exemplary embodiment, the display substrate further includes a plurality of signal connection lines located in the bezel region, a plurality of signal lines located in the display region and a bonding region located at a side of the display region, at least a portion of the signal connection lines are arranged so that one end is electrically connected with the plurality of signal lines respectively, and the other end is connected with the bonding region; The at least a portion of the signal connection lines are located in at least one corner region of the bezel region and is arranged in the first conductive layer and the second conductive layer; Orthographic projections of the at least a portion of the signal connection lines on the base substrate are at least partially overlapped with an orthographic projection of the power supply auxiliary line on the base substrate.

In an exemplary embodiment, orthographic projections of the signal connection lines located in the bezel region on the base substrate are within a range of an orthographic projection of the power supply auxiliary line on the base substrate.

In an exemplary embodiment, the plurality of signal lines include a plurality of data lines, the at least a portion of the signal connection lines include a plurality of first signal connection lines disposed in the first conductive layer, a plurality of second signal connection lines disposed in the second conductive layer, and the plurality of data lines are disposed in the second source-drain metal layer; The plurality of first signal connection lines and the plurality of second signal connection lines are alternately arranged in a direction away from the display region.

In an exemplary embodiment, the display substrate further includes at least one initial signal supply line located in the second source-drain metal layer; The at least one initial signal supply line is located in the bezel region, and in a corner region of the bezel region where the power supply auxiliary line is located, the at least one initial signal supply line is located at a side of the power supply auxiliary line away from the display region.

In an exemplary embodiment, the display substrate further includes a plurality of gate driving circuits, the plurality of gate driving circuits and the at least one initial signal supply line are located in different film layers; At least a portion of the gate driving circuits are located in at least one corner region of the bezel region and between the power supply auxiliary line and the first power supply line; The at least one initial signal supply line is located between the plurality of gate driving circuits and the power supply auxiliary line in a corner region of the bezel region where the power supply auxiliary line is located, or an orthographic projection of the at least one initial signal supply line on the base substrate is at least partially overlapped with orthographic projections of the plurality of gate driving circuits on the base substrate.

In an exemplary embodiment, the power supply auxiliary line is electrically connected to the at least a portion of the first power supply connection lines; The at least a portion of the first power supply connection lines extend along a first direction and extend from at least one corner region of the bezel region where the power supply auxiliary line is located to at least one corresponding corner region of the display region; The at least a portion of the second power supply connection lines are located in the display region and extends in a second direction, and the at least a portion of the first power supply connection lines and the at least a portion of the second power supply connection lines form a mesh structure in at least one corner region of the display region.

In an exemplary embodiment, in a direction perpendicular to a plane where the display substrate is located, the display substrate includes a base substrate and a first conductive layer, a second conductive layer, a first source-drain metal layer, and a second source-drain metal layer stacked on the base substrate sequentially; the plurality of first power supply connection lines are located in the first source-drain metal layer, the plurality of second power supply connection lines are located in the second source-drain metal layer, and the first power supply line is located at a side of the power supply auxiliary line away from the display region; the first power supply line is of a single-layer structure located in the first source-drain metal layer or the second source-drain metal layer, or the first power supply line is of a double-layer structure located in the first source-drain metal layer and the second source-drain metal layer.

In an exemplary embodiment, the display substrate further includes at least one initial signal supply line; The at least one initial signal supply line is located in the bezel region, and in a corner region of the bezel region where the power supply auxiliary line is located, the at least one initial signal supply line is located between the power supply auxiliary line and the display region.

In an exemplary embodiment, the display substrate further includes a plurality of gate driving circuits located in the first conductive layer, the second conductive layer, and the first source-drain metal layer; at least a portion of the gate driving circuits are located in at least one corner region of the bezel region and at a side of the power supply auxiliary line away from the at least one initial signal supply line.

In an exemplary embodiment, the at least one initial signal supply line and the power supply auxiliary line are located in one of the first source-drain metal layer and the second source-drain metal layer; or the at least one initial signal supply line and the power supply auxiliary line are of a double-layer structure located in the first source-drain metal layer and the second source-drain metal layer; or one of the at least one initial signal supply line and the power supply auxiliary line is located in one of the first source-drain metal layer and the second source-drain metal layer, and the other is of a double-layer structure located in the first source-drain metal layer and the second source-drain metal layer; The at least one initial signal supply line and the power supply auxiliary line are located between the plurality of gate driving circuits and the display region in a corner region of the bezel region where the power supply auxiliary line is located.

In an exemplary embodiment, the at least one initial signal supply line and the power supply auxiliary line are of a single-layer structure located in the second source-drain metal layer; orthographic projections of the at least one initial signal supply line and the power supply auxiliary line on the base substrate are at least partially overlapped with orthographic projections of the plurality of gate driving circuits on the base substrate.

In an exemplary embodiment, the display substrate further includes a plurality of first transfer connection electrodes disposed on at least one film layer of the first conductive layer and the second conductive layer; The plurality of first transfer connection electrodes are located in at least one corner region of the bezel region where the power supply auxiliary line is located, and are arranged along an extension direction of the power supply auxiliary line, one ends of the plurality of first transfer connection electrodes are electrically connected with the power supply auxiliary line, and the other ends of the plurality of first transfer connection electrodes are electrically connected with a plurality of first power supply connection lines respectively.

In an exemplary embodiment, the display substrate further includes a third source-drain metal layer, at least one of the at least one initial signal supply line and the power supply auxiliary line is located in the third source-drain metal layer.

In an exemplary embodiment, the at least a portion of the first power supply connection lines extend in the first direction to a non-corner region of the display region, and the at least a portion of the second power supply connection lines extend in the second direction to the non-corner region of the display region; or The at least a portion of the first power supply connection lines penetrate through the display region in the first direction and extend from one of corner regions of the display region to a corner region on an opposite side of the display region along the first direction; the at least a portion of the second power supply connection lines penetrate through the display region in the second direction and extend from one of corner regions of the display region to a corner region on an opposite side of the display region along the second direction.

In an exemplary embodiment, a boundary of at least one corner region of the display region and at least one corresponding corner region of the bezel region are all in a shape of an arc, in at least one corner region of the bezel region, the power supply auxiliary line, the at least one initial signal supply line and the first power supply line are all in a shape of an arc consistent with a shape of a corner region of the bezel region in which they are located, the power supply auxiliary line and the first power supply line are an integrally formed structure.

In an exemplary embodiment, the display region includes a plurality of sub-pixels arranged in a plurality of arrays, and in the second direction, a pitch between two adjacent first power supply connection lines is consistent with a width of a sub-pixel row in the second direction; in the first direction, a pitch between two adjacent second power supply connection lines is consistent with a width of at least one sub-pixel column along the first direction.

In an exemplary embodiment, the display substrate further includes a common electrode layer located on a side of the second source-drain metal layer away from the base substrate, and at least a portion of the power supply connection lines are electrically connected to the common electrode layer.

In an exemplary embodiment, the display substrate further includes: a special-shaped display region and a special-shaped bezel region; A special-shaped region power supply line is located in the special-shaped bezel region and arranged in at least one film layer of the first source-drain metal layer and the second source-drain metal layer; A plurality of special-shaped region second power supply connection lines, which extend from the special-shaped bezel region to the special-shaped display region, are arranged in the first source-drain metal layer, and at least a portion of the special-shaped region second power supply connection lines are electrically connected with the special-shaped region power supply line.

In an exemplary embodiment, the display substrate further includes a plurality of special-shaped region first power supply connection lines; The plurality of special-shaped region first power supply connection lines are located in the special-shaped bezel region and arranged in the first source-drain metal layer; at least a portion of the special-shaped region first power supply connection lines are electrically connected with the special-shaped region power supply line and at least a portion of the special-shaped region second power supply connection lines; an extension direction of the plurality of special-shaped region first power supply connection lines intersects an extension direction of the plurality of special-shaped region second power supply connection lines; the special-shaped region power supply line, the at least a portion of the special-shaped region first power supply connection lines and the at least a portion of the special-shaped region second power supply connection lines form a mesh structure in the special-shaped bezel region.

In an exemplary embodiment, the display substrate further includes a plurality of special-shaped region first signal connection lines and a plurality of special-shaped region second signal connection lines; The plurality of special-shaped region first signal connection lines and the plurality of special-shaped region second signal connection lines are located in the special-shaped bezel region, the plurality of special-shaped region first signal connection lines are arranged in the first conductive layer, and the plurality of special-shaped region second signal connection lines are arranged in the second conductive layer; The plurality of special-shaped region first signal connection lines and the plurality of special-shaped region second signal connection lines are alternately arranged in a direction away from the display region; Orthographic projections of at least a portion of the special-shaped first signal connection lines and at least a portion of the special-shaped second signal connection lines on the base substrate are at least partially overlapped with an orthographic projection of the special-shaped region power supply line on the base substrate.

In a second aspect, an embodiment of the present disclosure further provides a display apparatus, including the display substrate according to any one of the embodiments described above.

Other aspects of the present disclosure may be comprehended after the drawings and the detailed descriptions are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of each component in the drawings do not reflect actual scales, but are only intended to schematically illustrate contents of the present disclosure.

FIG. 1 is a schematic diagram of a structure of a display apparatus.

FIG. 2 is a schematic diagram of a structure of a display apparatus.

FIG. 3 is a schematic diagram of a partial sectional structure of a display region of a display substrate;

FIG. 4 is an equivalent circuit diagram of a pixel circuit;

FIG. 5 is a schematic diagram of a structure of a display apparatus.

FIG. 6a shows a schematic diagram of a structure of a display substrate according to an embodiment of the present disclosure.

FIG. 6b shows a schematic diagram of a structure of a display substrate according to an embodiment of the present disclosure.

FIG. 7a shows a schematic diagram of a structure of a display substrate according to an embodiment of the present.

FIG. 7b shows a schematic diagram of a structure of a display substrate according to an embodiment of the present.

FIG. 8 shows a partially enlarged schematic diagram of a first corner region of a display substrate in at least one exemplary embodiment of the present disclosure;

FIG. 9 shows a schematic diagram of a planar structure of a second source-drain metal layer in FIG. 8;

FIG. 10 shows a schematic diagram of a planar structure of a first conductive layer and a second conductive layer in FIG. 8;

FIG. 11 shows a partially enlarged schematic diagram of a first corner region of a display substrate in at least one exemplary embodiment of the present disclosure;

FIG. 12 shows a schematic diagram of a planar structure of a second source-drain metal layer in FIG. 11;

FIG. 13 shows a partially enlarged schematic diagram of a first corner region of a display substrate in at least one exemplary embodiment of the present disclosure;

FIG. 14 shows a schematic diagram of a planar structure of the first source-drain metal layer and a second source-drain metal layer in FIG. 13;

FIG. 15 shows a schematic diagram of a connection structure of a first transfer connection electrode, a power supply auxiliary line and a first power supply connection line in FIG. 13;

FIG. 16 shows a schematic diagram of a planar structure of a third source-drain metal layer according to at least one embodiment of the present disclosure;

FIG. 17 shows a schematic diagram of a sectional structure of a display substrate according to at least one embodiment of the present disclosure.

FIG. 18 shows a schematic diagram of a structure of a special-shaped display region according to at least one embodiment of the present disclosure;

FIG. 19 shows a schematic diagram of a planar structure of a first source-drain metal layer in a structure shown in FIG. 18;

FIG. 20 shows a schematic diagram of a planar structure of a first conductive layer and a second conductive layer in FIG. 18;

FIG. 21 shows a schematic diagram of a structure of a display substrate according to an embodiment of the present disclosure.

FIG. 22a is an equivalent circuit diagram of a pixel circuit.

FIG. 22b is an equivalent circuit diagram of a pixel circuit;

FIG. 23 is an equivalent circuit diagram of a pixel circuit;

FIG. 24 is a schematic diagram of a structure of a pixel drive circuit.

FIG. 25 shows a schematic diagram of a planar structure after a pattern of a shielding layer in a pixel driving circuit is formed on a base substrate;

FIG. 26A shows a schematic diagram of a planar structure after a first semiconductor layer is formed in a pixel driving circuit;

FIG. 26B shows a schematic diagram of a planar structure of a first semiconductor layer in a pixel driving circuit;

FIG. 27A shows a schematic diagram of a planar structure after a first conductive layer is formed in a pixel driving circuit;

FIG. 27B shows a schematic diagram of a planar structure of a first conductive layer in a pixel driving circuit;

FIG. 28A shows a schematic diagram of a planar structure after a second conductive layer in a pixel driving circuit is formed;

FIG. 28B shows a schematic diagram of a planar structure of a second conductive layer in a pixel driving circuit;

FIG. 29A shows a schematic diagram of a planar structure after a second semiconductor layer is formed in a pixel driving circuit;

FIG. 29B shows a schematic diagram of a planar structure of a second semiconductor layer in a pixel driving circuit;

FIG. 30A shows a schematic diagram of a planar structure after a third conductive layer is formed in a pixel driving circuit;

FIG. 30B shows a schematic diagram of a planar structure of a third conductive layer in a pixel driving circuit;

FIG. 31 shows a schematic diagram of a planar structure in which a pattern of a sixth insulating layer is formed in a pixel driving circuit;

FIG. 32A shows a schematic diagram of a planar structure after a first source-drain metal layer is formed in a pixel driving circuit;

FIG. 32B shows a schematic diagram of a planar structure of a first source-drain metal layer in a pixel driving circuit;

FIG. 33 shows a schematic diagram of a planar structure in which a seventh insulating layer and a pattern of a first planarization layer are formed in a pixel driving circuit;

FIG. 34A shows a schematic diagram of a planar structure after a second source-drain metal layer is formed in a pixel driving circuit;

FIG. 34B shows a schematic diagram of a planar structure of a second source-drain metal layer in a pixel driving circuit;

FIG. 35 shows a schematic diagram of a planar structure after a pattern of a shielding layer in a pixel driving circuit is formed on a base substrate;

FIG. 36A shows a schematic diagram of a planar structure after a first semiconductor layer is formed in a pixel driving circuit;

FIG. 36B shows a schematic diagram of a planar structure of a first semiconductor layer in a pixel driving circuit;

FIG. 37A shows a schematic diagram of a planar structure after a first conductive layer is formed in a pixel driving circuit;

FIG. 37B shows a schematic diagram of a planar structure of a first conductive layer in a pixel driving circuit;

FIG. 38A shows a schematic diagram of a planar structure after a second conductive layer in a pixel driving circuit is formed;

FIG. 38B shows a schematic diagram of a planar structure of a second conductive layer in a pixel driving circuit;

FIG. 39A shows a schematic diagram of a planar structure after a second semiconductor layer is formed in a pixel driving circuit;

FIG. 39B shows a schematic diagram of a planar structure of a second semiconductor layer in a pixel driving circuit;

FIG. 40A shows a schematic diagram of a planar structure after a third conductive layer in a pixel driving circuit is formed;

FIG. 40B shows a schematic diagram of a planar structure of a third conductive layer in a pixel driving circuit;

FIG. 41 shows a schematic diagram of a planar structure in which a pattern of a sixth insulating layer is formed in a pixel driving circuit;

FIG. 42A shows a schematic diagram of a planar structure after a first source-drain metal layer is formed in a pixel driving circuit;

FIG. 42B shows a schematic diagram of a planar structure of a first source-drain metal layer in a pixel driving circuit;

FIG. 43 shows a schematic diagram of a planar structure in which a seventh insulating layer and a pattern of a first planarization layer are formed in a pixel driving circuit;

FIG. 44A shows a schematic diagram of a planar structure after a second source-drain metal layer in a pixel driving circuit is formed;

FIG. 44B shows a schematic diagram of a planar structure of a second source-drain metal layer in a pixel driving circuit;

FIG. 45 is a schematic diagram of a structure of a pixel drive circuit.

### DETAILED DESCRIPTION

The embodiments of the present disclosure will be described below with reference to the drawings in detail. Embodiments may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating orientations or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, a transistor refers to an element which at least includes three terminals, i.e., a gate (gate electrode), a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In addition, the gate may also be referred to as a control electrode. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification. In embodiments of the present disclosure, the gate may be referred to as a control electrode.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, guide angles, curved edges and deformations thereof may exist.

In the specification, “about” and “substantially” refer to that a boundary is not defined strictly and a case within a process and measurement error range is allowed. In the present disclosure, “substantially the same” refers to a case where numerical values differ by less than 10%.

In the present specification, “A extends along a B direction” means that A may include a main portion and a secondary portion connected to the main portion, the main portion is a line, a line segment, or a strip-shaped body, the main portion extends along the B direction, and a length of the main portion extending along the B direction is greater than a length of the secondary portion extending along another direction. “A extends in a B direction” in the present specification always means “a main portion of A extends in a B direction”.

“A and B are of a same layer structure” mentioned in the present specification means that A and B are formed simultaneously through a same patterning process. A “same layer” does not always mean that thicknesses of layers or heights of layers are the same in a section diagram. “An orthographic projection of A contains an orthographic projection of B” means that the orthographic projection of B falls within a range of the orthographic projection of A, or the orthographic projection of A covers the orthographic projection of B.

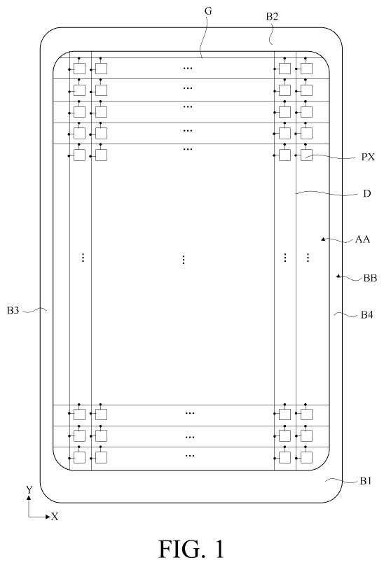

FIG. 1 is a schematic diagram of the appearance of a display apparatus, which has a rectangular shape with rounded chamfers. The display apparatus may include a display substrate. In some examples, the display substrate may be a closed polygon including linear edges, a circle or an ellipse including a curved edge, a semicircle or semi-ellipse including a linear edge and a curved edge, or the like. In some examples, when the base substrate has a linear edge, at least some corners of the base substrate may be curved. When the base substrate is in a shape of a rectangle, a portion at a position where adjacent linear edges intersect with each other may be replaced by a curve with a predetermined curvature. Herein, the curvature may be set according to different positions of the curve. For example, the curvature may be changed according to a starting position of the curve, a length of the curve, etc.

In some examples, as shown in FIG. 1, the display substrate may include a display region AA and a peripheral region BB located at a periphery of the display region AA. In some examples, the display region AA may include a first edge (lower edge) and a second edge (upper edge) oppositely disposed in the second direction Y, and a third edge (left edge) and a fourth edge (right edge) oppositely disposed in the first direction X. Adjacent edges can be connected by an arcuate chamfer to form a quadrilateral shape with a rounded chamfer. In some examples, the peripheral region BB may include a first bezel (lower bezel) B1 and a second bezel (upper bezel) B2 oppositely disposed in the second direction Y, and a third bezel (left bezel) B3 and a fourth bezel (right bezel) B4 oppositely disposed in the first direction X. The first bezel B1 is in communication with the third bezel B3 and the fourth bezel B4, and the second bezel B2 is in communication with the third bezel B3 and the fourth bezel B4.

In some examples, as shown in FIG. 1, the display region AA at least includes a plurality of sub-pixels PX, a plurality of gate lines G, and a plurality of data lines D. The plurality of gate lines G may extend in the first direction X, and the plurality of data lines D may extend in the second direction Y. Orthographic projections of the plurality of gate lines G on the base substrate and orthographic projections of the plurality of data lines D on the base substrate intersect to form a plurality of sub-pixel regions, and one of the sub-pixels PX is disposed in each sub-pixel region. The plurality of data lines D are electrically connected with a plurality of sub-pixels PX and may be configured to provide data signals to the plurality of sub-pixels PX. The plurality of gate lines G are electrically connected with the plurality of sub-pixels PX and may be configured to provide gate control signals to the plurality of sub-pixels PX. In some examples, the gate control signal may include a scan signal and a light emitting control signal.

In some examples, as shown in FIG. 1, the first direction X may be an extension direction of the gate line G in the display region (row direction), and the second direction Y may be an extension direction of the data line D in the display region (column direction). The first direction X and the second direction Y may be perpendicular to each other.

In some examples, a pixel unit of the display region AA may include three sub-pixels which are a red sub-pixel, a green sub-pixel, and a blue sub-pixel respectively. However, the embodiment is not limited thereto. In some examples, one pixel unit may include four sub-pixels, and the four sub-pixels are a red sub-pixel, a green sub-pixel, a blue sub-pixel, and a white sub-pixel respectively.

In some examples, a shape of a sub-pixel may be a rectangle, a rhombus, a pentagon, or a hexagon. When one pixel unit includes three sub-pixels, the three sub-pixels may be arranged in parallel in a horizontal direction, in parallel in a vertical direction, or in a delta-shaped form. When one pixel unit includes four sub-pixels, the four sub-pixels may be arranged in parallel in a horizontal direction, in parallel in a vertical direction, or in a square. However, the embodiment is not limited thereto.

In some examples, a sub-pixel may include a pixel circuit and a light emitting element electrically connected with the pixel circuit. The pixel circuit may include a plurality of transistors and at least one capacitor, for example, the pixel circuit may be of a 3TIC (i.e., three transistors and one capacitor) structure, a 7TIC (i.e., seven transistors and one capacitor) structure, a 5TIC (i.e., five transistors and one capacitor) structure, an 8TIC (eight transistors and one capacitor) structure, or a 8T2C (eight transistors and two capacitors) structure, or the like.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected to a corresponding pixel circuit. However, the embodiment is not limited thereto.

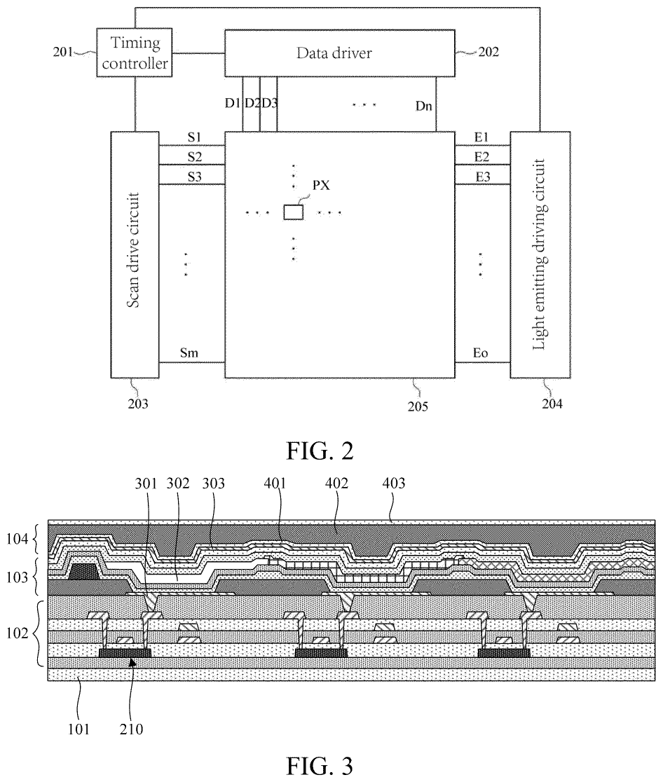

FIG. 2 is a schematic diagram of a structure of a display apparatus. In some examples, as shown in FIG. 2, the display apparatus may include a timing controller 201, a data driver 202, a scan drive circuit 203, a light emitting drive circuit 204 and a display substrate 205. In some examples, the display region of the display substrate 205 may include a plurality of sub-pixels PX arranged regularly. The scan drive circuit 203 may be configured to supply a scan signal to a sub-pixel PX along a scan line. The data driver 202 may be configured to supply a data voltage to a sub-pixel PX along a data line. The light emitting drive circuit 204 may be configured to supply a light emitting control signal to a sub-pixel PX along a light emitting control line. The timing controller 201 may be configured to control the scan drive circuit 203, the light emitting drive circuit 204 and the data driver 202.

In some examples, the timing controller 201 may provide a gray-scale value and a control signal suitable for a specification of the data driver 202 to the data driver 202; the timing controller 201 may provide a scan clock signal, a scan start signal, etc., suitable for a specification of the scan drive circuit 203 to the scan drive circuit 203; the timing controller 201 may provide a light-emitting clock signal, a light-emitting start signal, etc., suitable for a specification of the light-emitting drive circuit 204 to the light-emitting drive circuit 204. The data driver 202 may generate a data voltage, which will be provided to data lines D1 to Dn, using the gray-scale value and the control signal received from the timing controller 201. For example, the data driver 202 may sample the gray-scale value using the clock signal and apply the data voltage corresponding to the gray-scale value to the data lines D1 to Dn using a sub-pixel row as a unit. The scan circuit 203 may receive the scan clock signal, the scan start signal, etc., from the timing controller 201 to generate a scan signal to be provided to scan lines S1 to Sm. For example, the scan drive circuit 203 may sequentially provide scan signals with on-level pulses to scan lines. In some examples, the scan drive circuit 203 may include a shift register and may generate a scan signal by means of sequentially transmitting a scan start signal provided in a form of an on-level pulse to a next-stage circuit under control of a scan clock signal. The light emitting drive circuit 204 may receive the light emitting clock signal, the light emitting start signal, etc., from the timing controller 201 to generate a light emitting control signal to be provided to light emitting control lines E1 to Eo. For example, the light-emitting drive circuit 204 may provide sequentially light-emitting start signals with off-level pulses to the light-emitting control lines. The light-emitting drive circuit 204 may include a shift register, and generate a light-emitting control signal by means of sequentially transmitting a light-emitting start signal provided in a form of an off-level pulse to a next-stage circuit under control of a light-emitting clock signal. Herein, n, m, and o are all natural numbers.

In some examples, the scan drive circuit and the light emitting drive circuit may be directly disposed on the display substrate. For example, the scan drive circuit may be disposed at the third bezel of the display substrate, and the light emitting drive circuit may be disposed at the fourth bezel of the display substrate. Or, the third bezel and the fourth bezel of the display substrate may be both provided with the scan drive circuit and the light emitting drive circuit. In some examples, the scan drive circuit and the light emitting drive circuit may be formed together with the sub-pixels in a process of forming the sub-pixels.

In some examples, the data driver may be disposed on an independent chip or printed circuit board to be connected to the sub-pixel through the signal access pin on the display substrate. For example, the data driver may be formed and disposed at the first bezel of the display substrate using a chip on glass, a chip on plastics, a chip on film, etc., to be connected to the signal access pin. The timing controller may be arranged separately from or integrally with the data driver. However, the embodiment is not limited thereto. In some examples, the data driver may be directly disposed on the display substrate.

FIG. 3 is a schematic diagram of a cross-sectional structure of a display substrate, which illustrates a structure of three sub-pixels of an OLED display substrate. As shown in FIG. 3, on a plane perpendicular to the display substrate, the display substrate may include a drive circuit layer 102 disposed on a base substrate 101, a light emitting structure layer 103 disposed on a side of the drive circuit layer 102 away from the base substrate 101, and an encapsulation layer 104 disposed on a side of the light emitting structure layer 103 away from the base substrate 101. In some possible implementations, the display substrate may include another film layer, such as a post spacer, which is not limited in the present disclosure.

In an exemplary implementation, the base substrate 101 may be a flexible base substrate, or may be a rigid base substrate. The drive circuit layer 102 of each sub-pixel may include a plurality of transistors and a storage capacitor constituting a pixel drive circuit. The light emitting structure layer 103 may include an anode 301 connected to a drain electrode of a driving transistor 210 through a via, an organic light emitting layer 302 connected to the anode 301, and a cathode 303 connected to the organic light emitting layer 302, which emits light of corresponding color under drive of the anode 301 and the cathode 303. The encapsulation layer 104 may include a first encapsulation layer 401, a second encapsulation layer 402, and a third encapsulation layer 403 that are stacked. The first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 so as to prevent external water vapor from entering the light-emitting structure layer 103.

In an exemplary implementation, the organic emitting layer 302 may include a Hole Injection Layer (HIL), a Hole Transport Layer (HTL), an Electron Block Layer (EBL), an Emitting Layer (EML), a Hole Block Layer (HBL), an Electron Transport Layer (ETL), and an Electron Injection Layer (EIL) which are stacked. In an exemplary embodiment, hole injection layers of all sub-pixels may be connected together to be a common layer, electron injection layers of all the sub-pixels may be connected together to be a common layer, hole transport layers of all the sub-pixels may be connected together to be a common layer, electron transport layers of all the sub-pixels may be connected together to be a common layer, hole block layers of all the sub-pixels may be connected together to be a common layer, emitting layers of adjacent sub-pixels may be overlapped slightly or may be isolated, and electron block layers of adjacent sub-pixels may be overlapped slightly or may be isolated.

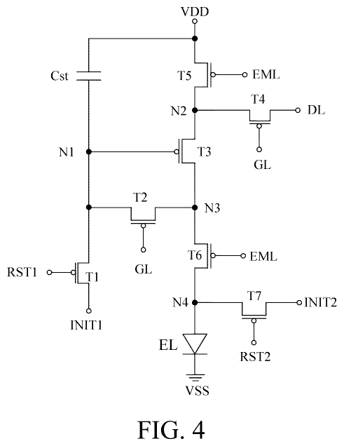

FIG. 4 is an equivalent circuit diagram of a pixel circuit. In some examples, as shown in FIG. 4, the pixel circuit of this example may include seven transistors (i.e. a first transistor T1 to a seventh transistor T7) and one storage capacitor Cst. A gate of the third transistor T3 is electrically connected with a first node N1, a first electrode of the third transistor T3 is electrically connected with a second node N2, and a second electrode of the third transistor T3 is connected with the third node N3. The third transistor T3 may be referred to as a drive transistor. A gate of the fourth transistor T4 is electrically connected with the first scan line GL, a first electrode of the fourth transistor T4 is electrically connected with the data line DL, and a second electrode of the fourth transistor T4 is electrically connected with the first electrode of the third transistor T3. The fourth transistor T4 may be referred to as a data writing transistor. A gate of the second transistor T2 is electrically connected with the first scan line GL, a first electrode of the second transistor T2 is electrically connected with a gate of the third transistor T3, and a second electrode of the second transistor T2 is electrically connected with a second electrode of the third transistor T3. The second transistor T2 may also be referred to as a threshold compensation transistor. A gate of the fifth transistor T5 is electrically connected with the light emitting control line EML, a first electrode of the fifth transistor T5 is electrically connected with the second power supply line VDD, and a second electrode of the fifth transistor T5 is electrically connected with the first electrode of the third transistor T3. A gate of the sixth transistor T6 is electrically connected with the light emitting control line EML, a first electrode of the sixth transistor T6 is electrically connected with the second electrode of the third transistor T3, and a second electrode of the sixth transistor T6 is electrically connected with an anode of the light emitting element EL. The fifth transistor T5 and the sixth transistor T6 may be referred to as light emitting control transistors. The first transistor T1 is electrically connected with the gate of the third transistor T3 and configured to reset the gate of the third transistor T3, and the seventh transistor T7 is electrically connected with the anode of the light emitting element EL and configured to reset the anode of the light emitting element EL. A gate of the first transistor T1 is electrically connected with a second scan line RST1, a first electrode of the first transistor T1 is electrically connected with a first initial signal line INIT1, and a second electrode of the first transistor T1 is electrically connected with the gate of the third transistor T3. A gate of the seventh transistor T7 is connected with the third scan line RST2, a first electrode of the seventh transistor T7 is connected with the second initial signal line INIT2, and a second electrode of the seventh transistor T7 is connected with the anode of the light emitting element EL. The first transistor T1 and the seventh transistor T7 may also be referred to as reset control transistors. A first capacitor plate of the storage capacitor Cst is electrically connected with the gate of the third transistor T3, and a second capacitor plate of the storage capacitor Cst is electrically connected with the second power supply line VDD.

In this example, the first node N1 is a connection point for the storage capacitor Cst, the first transistor T1, the third transistor T3 and the second transistor T2, the second node N2 is a connection point for the fifth transistor T5, the fourth transistor T4, and the third transistor T3, the third node N3 is a connection point for the third transistor T3, the second transistor T2, and the sixth transistor T6, the fourth node N4 is a connection point for the sixth transistor T6, the seventh transistor T7, and the light emitting element EL.

In some examples, the first transistor T1 to the seventh transistor T7 may be P-type transistors or may be N-type transistors. Use of a same type of transistors in a pixel drive circuit may simplify a process flow, reduce a process difficulty of a display panel, and improve a product yield. In some possible embodiments, the first transistor T1 to the seventh transistor T7 may include a P-type transistor and an N-type transistor.

In some examples, the second power supply line VDD may be configured to provide a constant second voltage signal for a pixel circuit, the first power supply line VSS may be configured to provide a constant first voltage signal to a pixel circuit, wherein the second voltage signal may be greater than the first voltage signal. The first scan line GL may be configured to provide a scan signal SCAN to the pixel circuit, the data line DL may be configured to provide a data signal DATA to the pixel circuit, the light emitting control line EML may be configured to provide a light emitting control signal EM to the pixel circuit, the second scan line RST1 may be configured to provide a first reset control signal RESET1 to the pixel circuit, and the third scan line RST2 may be configured to provide a second reset control signal RESET2 to the pixel circuit. In some examples, a second scan line RST1 for an n-th row of pixel circuits may be electrically connected with a first scan line GL for an (n−1)-th row of pixel circuits, so as to be inputted with a scan signal SCAN(n−1), that is, a first reset control signal RESET1(n) is the same as the scan signal SCAN(n−1). A third scan line RST2 for the n-th row of pixel circuits may be electrically connected with a first scan line GL for the n-th row of pixel circuits, so as to be inputted with a scan signal SCAN(n), that is, a second reset control signal RESET2(n) may be the same as the scan signal SCAN(n). Herein, n is an integer greater than 0. Thus, signal lines of the display substrate may be reduced, and a narrow bezel design of the display substrate may be achieved. However, the embodiment is not limited thereto.

In some examples, the first initial signal line INIT1 is configured to provide a first initial signal to the pixel circuit, and the second initial signal line INIT2 is configured to provide a second initial signal to the pixel circuit. For example, the first initial signal may be different from the second initial signal. The first initial signal and the second initial signal may be constant voltage signals, and their magnitudes may be between a first voltage signal and a second voltage signal, but not limited to this. In other examples, the first initial signal and the second initial signal may be the same and only the first initial signal line may be provided to provide the first initial signal.

In order to better meet people's needs for various functions and better screen experience (for example, the display screen with ultra-high screen-to-body ratio), the design of narrow bezel display screen has gradually become the mainstream form of display devices. However, in some implementations, some signal lines and circuits within the display panel are arranged in such a manner that the display panel cannot achieve a narrow bezel.

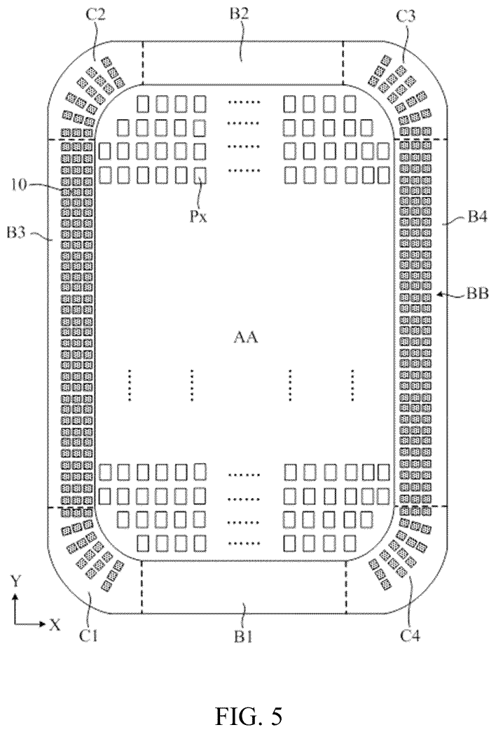

In order to maximize the display region and the extremely narrow bezel in the display screen, a curved edge design can be adopted on a large-size display panel, that is, the GOA rotates together with the Layout of pixel circuits. As shown in FIG. 5, which is a schematic diagram of a structure of a display apparatus, the display apparatus can include a display panel, the display panel can include a display substrate, and the display substrate can include: a display region AA and a bezel region BB located around the display region, the display region AA can include at least one corner region, and the bezel region BB can include at least one corner region, at least one corner region of the display region AA corresponds to at least one corner region of the bezel region BB; a plurality of sub-pixels Px are located in the display region AA; at least part of the plurality of sub-pixels Px are located in at least one corner region of the display region AA and are arranged in a stepped shape; at least one corner region located in the bezel region BB may be provided with a plurality of driving circuits 10, which may be Gate Driver on Array (GOA for short) circuits, which may be gate driving circuits arranged to supply gate driving signals to sub-pixels Px in the display region AA (for example, the gate driving signals may be signals provided to the first scan line GL, the second scan line RST1, the third scan line RST2, and the light emitting control line EML in FIG. 4).

In some exemplary embodiments, as shown in FIG. 5, the bezel region BB may further include: a first bezel region B1 and a second bezel region B2 located on two sides of the display region AA in the second direction Y, a third bezel region B3 and a fourth bezel region B4 located on two sides of the display region AA in the first direction X; the at least one corner region of the bezel region BB may include a first corner region C1 connecting the first bezel region B1 and the third bezel region B3, a second corner region C2 connecting the third bezel region B3 and the second bezel region B2, a third corner region C3 connecting the second bezel region B2 and the fourth bezel region B4, and a fourth corner region C4 connecting the fourth bezel region B4 and the first bezel region B1.

In some exemplary embodiments, as shown in FIG. 5, the plurality of driving circuits 10 may be located in the third bezel region B3, the fourth bezel region B4, the first corner region C1, the second corner region C2, the third corner region C3, and the fourth corner region C4.

Cathodes of light emitting elements EL are usually provided as a common electrode layer, the first power supply line VSS provides a first voltage signal to the common electrode layer, and the first voltage signal is provided from the common electrode layer to a plurality of light emitting elements EL. Because the first power supply line VSS is usually not provided in a corner (rounded corner) region of the display panel, a voltage drop (VSS Drop) of the common electrode layer in the corner (rounded corner) region is large, so that the display uniformity of the display panel is reduced in the corner (rounded corner) region, and there exists a problem that the display uniformity of the display panel is not high.

Embodiments of the present disclosure provide a display substrate, which can include: a display region and a bezel region located around the display region, wherein the display region comprises at least one corner region, the bezel region comprises at least one corner region, and the at least one corner region of the display region corresponds to the at least one corner region of the bezel region; A power supply auxiliary line located in at least one corner region of the bezel region and arranged to be electrically connected with a first power supply line; A plurality of power supply connection lines, at least a portion of which are arranged to be electrically connected with the power supply auxiliary line, and extend from a corner region of the bezel region where the power supply auxiliary line is located to a corresponding corner region of the display region.

In the display substrate according to the present embodiment, a power supply auxiliary line connected with the first power supply line is provided in the corner region of the bezel region, and a plurality of power supply connection lines are provided, at least a portion of the power supply connection lines are arranged to be electrically connected with the power supply auxiliary line, and extend from a corner region of the bezel region where the power supply auxiliary line is located to a corresponding corner region of the display region, so that a signal of the first power supply line can be provided to the corner region of the display region through the at least a portion of the power supply connection lines and the power supply auxiliary line, so as to improve the display uniformity of the display substrate.

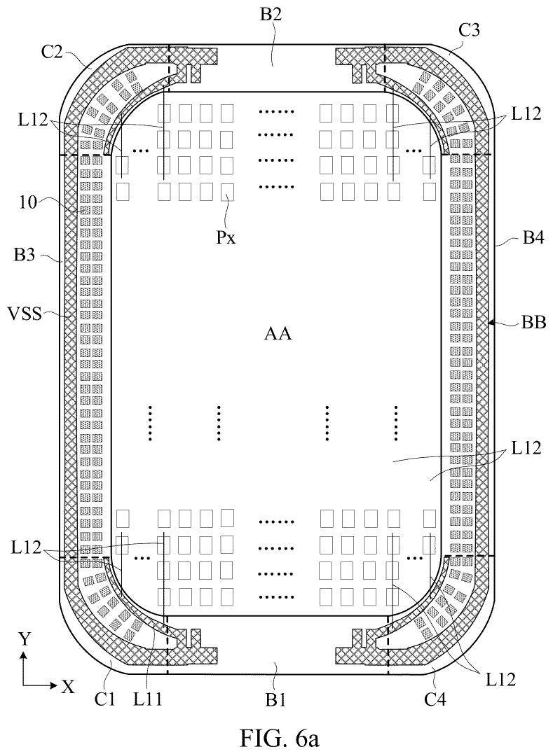

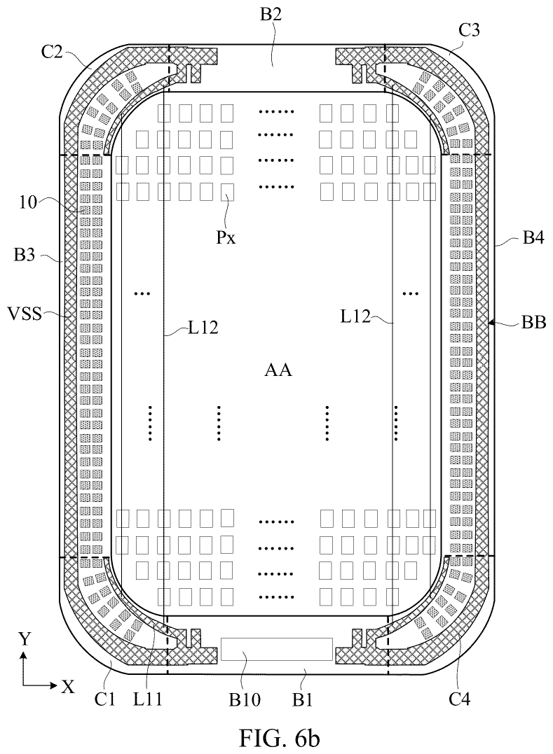

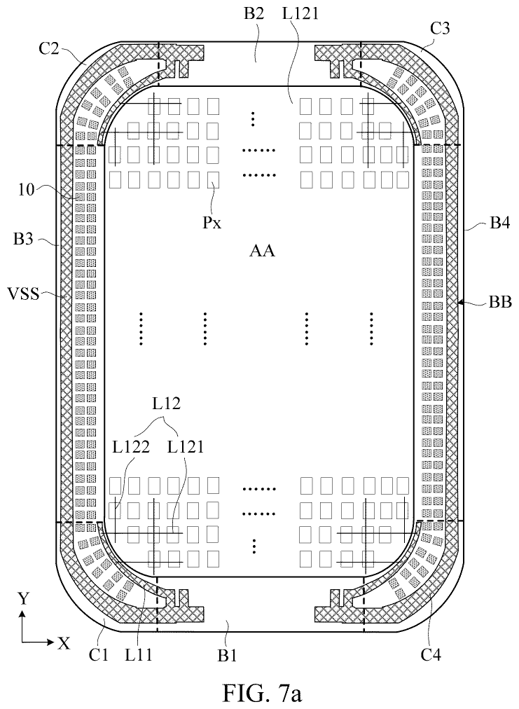

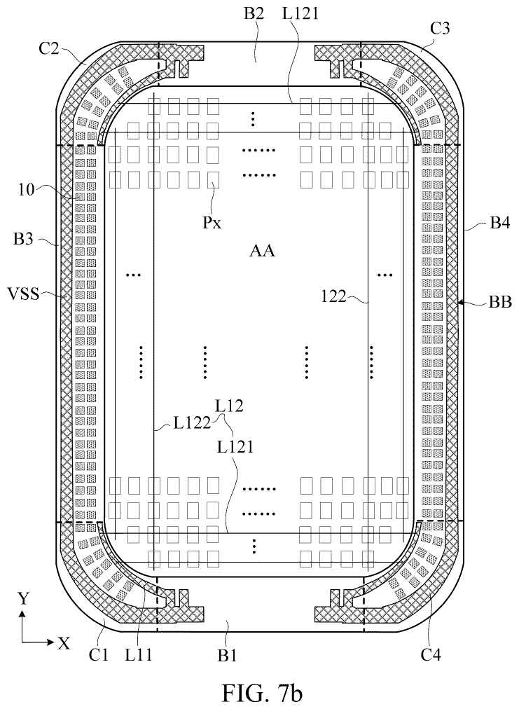

As shown in FIGS. 6a to 7b, the display substrate according to the present disclosure may include: a display region AA and a bezel region BB located around the display region AA, the display region AA may include at least one corner region, the bezel region BB which may include at least one corner region, the at least one corner region of the display region AA corresponds to the at least one corner region of the bezel region BB; A power supply auxiliary line L11 located in at least one corner region of the bezel region BB and arranged to be electrically connected with the first power supply line VSS; A plurality of power supply connection lines L12, at least a portion of which are arranged to be electrically connected to the power supply auxiliary line L11, and extends from a corner region of the bezel region BB where the power supply auxiliary line L11 is located to a corresponding corner region of the display region AA.

In an exemplary embodiment, as shown in FIGS. 7a and 7b, the plurality of power supply connection lines L12 may include a plurality of first power supply connection lines L121 and a plurality of second power supply connection lines L122, an extension direction of the plurality of first power supply connection lines L121 intersects an extension direction of the plurality of second power supply connection lines L122, and at least a portion of the first power supply connection lines L121 and at least a portion of the second power supply connection lines L122 are electrically connected.

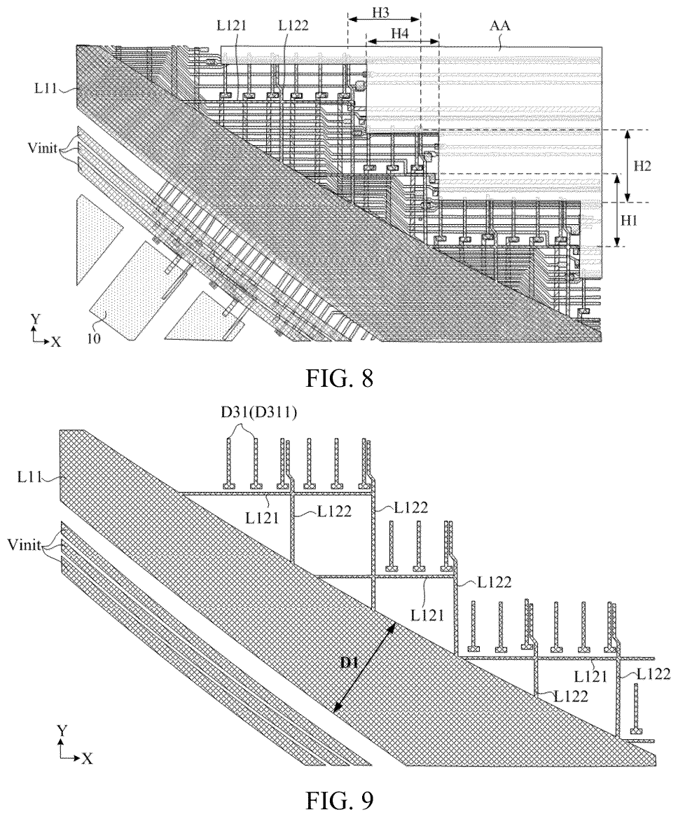

In an exemplary embodiment, as shown in FIGS. 8 and 9, which are schematic diagrams of enlarged structures of a first corner region C1 of the bezel region BB and a corresponding corner region of the display region in FIGS. 6a and 6b, at least a portion of the first power supply connection lines L121 are located in at least one corner region of the bezel region BB and extend in the first direction X.

At least a portion of the second power supply connection lines L122 extend in the second direction Y and extend from at least one corner region of the bezel region BB where the power supply auxiliary line L11 is located to at least one corresponding corner region of the display region AA.

The power supply auxiliary line L11 is electrically connected to at least a portion of the first power supply connection lines L121 and at least a portion of the second power supply connection lines L122, respectively. The power supply auxiliary line L11, at least a portion of the first power supply line and at least a portion of the second power supply line form a mesh structure in at least one corner region of the bezel region BB where the power supply auxiliary line L11 is located.

In an exemplary embodiment, as shown in FIGS. 6a to 7b and 9, a width D1 of the power supply auxiliary line L11 gradually decreases from an end connected to the first power supply line VSS to an end away from the first power supply line VSS. The width D1 of the power supply auxiliary line L11 is gradually changed, which can make the current density on the power supply auxiliary line L11 transition uniformly, and the overall display is relatively uniform, thus improving the display effect.

In an exemplary embodiment, the width D1 of the power supply auxiliary line L11 is a minimum of 15 microns to 30 microns, for example, the width D1 of the power supply auxiliary line L11 is a minimum of 20 um; the width D1 of the power supply auxiliary line L11 is a maximum of 130 microns to 160 microns, for example, the width D1 of the power supply auxiliary line L11 is a maximum of 150 microns. In an exemplary embodiment, the ratio of the maximum value of the width D1 of the power supply auxiliary line L11 to the minimum value of the width D1 of the power supply auxiliary line L11 may be 4.3 to 10.7, for example, the ratio of the maximum value of the width D1 of the power supply auxiliary line L11 to the minimum value of the width D1 of the power supply auxiliary line L11 may be 7.5 (e.g. the maximum value is 150 microns and the minimum value is 20 microns). In the embodiment of the present disclosure, the larger the width D1 of the power supply auxiliary line L11, the better, and the larger the value of D1, the smaller the resistance of the power supply auxiliary line L11. However, due to the limitation of space layout, in some regions, the power supply auxiliary line is designed to be narrower, but there should not be a sudden change in line width to avoid burns because of current concentration.

In an exemplary embodiment, in a direction perpendicular to a plane where the display substrate is located, the display substrate may include a base substrate and a first conductive layer, a second conductive layer, a first source-drain metal layer, and a second source-drain metal layer stacked on the base substrate sequentially; a power supply auxiliary line L11, a first power supply line VSS, a plurality of first power supply connection lines L121, and a plurality of second power supply connection lines L122 may be located in the second source-drain metal layer, and the first power supply line VSS may be located at a side of the power supply auxiliary line L11 away from the display region AA (as shown in FIGS. 6a to 7b).

In an exemplary embodiment, as shown in FIGS. 6b, 8 to 10, the display substrate may further include a plurality of signal connection lines L31 located in the bezel region BB, a plurality of signal lines D31 located in the display region AA, and a bonding region B10 located on a side of the display region AA, at least a portion of the signal connection lines L31 are arranged so that one ends are electrically connected with the plurality of signal lines D31, respectively, and the other ends are connected with the bonding region B10.

At least a portion of the signal connection lines L31 are located in at least one corner region of the bezel region BB and are provided in the first conductive layer and the second conductive layer.

Orthographic projections of at least a portion of the signal connection lines L31 on the base substrate overlap at least partially an orthographic projection of the power supply auxiliary line L11 on the base substrate.

As shown in FIG. 6b, the bonding region B10 may be provided on the first bezel B1 (lower bezel) of the display substrate.

In an exemplary embodiment, orthographic projections of the signal connection lines L31 located in the bezel region BB on the base substrate are within a range of an orthographic projection of the power supply auxiliary line L11 on the base substrate. For example, the orthographic projections of the signal connection lines L31 located in the bezel region BB on the base substrate may completely coincide with the orthographic projection of the power supply auxiliary line L11 on the base substrate, or the orthographic projection of the power supply auxiliary line L11 on the base substrate covers the orthographic projections of the signal connection lines L31 located in the bezel region BB on the base substrate. In embodiments of the present disclosure, a complete coincidence may be a coincidence that is permissible within a process deviation range.

In an exemplary embodiment, in a direction away from the display region AA, a size of at least a portion of the signal connection lines L31 located in the bezel region BB is consistent with a size (i.e., width D1) of the power supply auxiliary line L11, so that an orthographic projection of the power supply auxiliary line L11 on the base substrate and orthographic projections of the at least a portion of the signal connection lines L31 on the base substrate at least partially overlap, and touch signals can be shielded by the power supply auxiliary line L11 to avoid interference with signals provided by the signal connection lines L31 to the data line D311. In an embodiment of the present disclosure, the direction away from the display region AA refers to a direction away from the display region AA in one of the directions in a plane parallel to the display substrate, for example, in a corner region of the display substrate, and the direction away from the display region AA may be a direction along a corner region of the display region AA to a corresponding corner region of the bezel region BB in a plane parallel to the display substrate.

In an exemplary embodiment, the plurality of signal lines D31 may include a plurality of data lines D311, and the at least a portion of the signal connection lines L31 may include a plurality of first signal connection lines L311 disposed in the first conductive layer and a plurality of second signal connection lines L312 disposed in the second conductive layer, and the plurality of data lines D311 are disposed in the second source-drain metal layer.

The plurality of first signal connection lines L311 and the plurality of second signal connection lines L312 are alternately arranged in a direction away from the display region AA.

FIG. 9 is a schematic diagram of a planar structure of a second source-drain metal layer in FIG. 8, and FIG. 10 is a schematic diagram of a planar structure of a first conductive layer and a second conductive layer in FIG. 8.

In an exemplary embodiment, as shown in FIGS. 8 and 9, the display substrate may further include at least one initial signal supply line Vinit located in the second source-drain metal layer.

The at least one initial signal supply line Vinit may be located in the bezel region BB, and in a corner region of the bezel region BB where the power supply auxiliary line L11 is located; and at least one initial signal supply line Vinit is located at a side of the power supply auxiliary line L11 away from the display region AA.

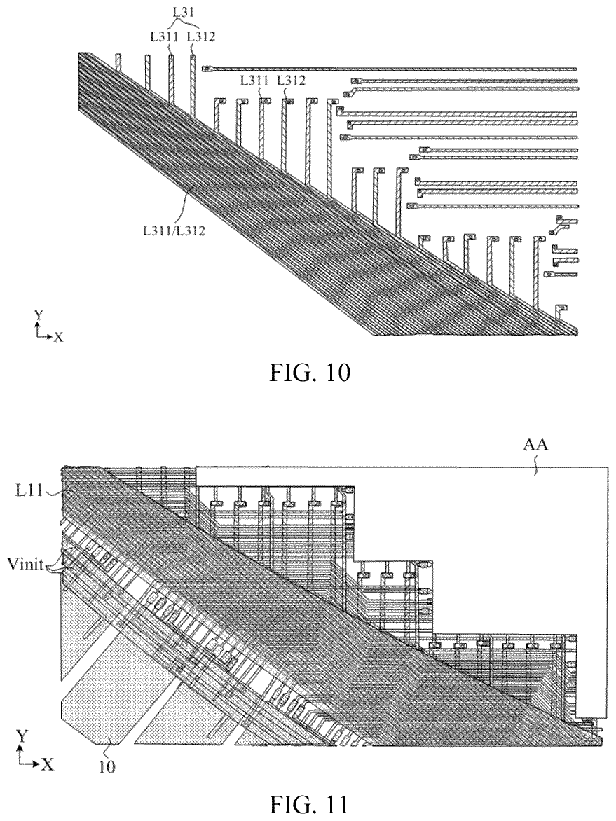

In an exemplary embodiment, as shown in FIGS. 8 and 11, the display substrate may further include a plurality of gate driving circuits 10, the plurality of gate driving circuits 10 and the at least one initial signal supply line Vinit are located in different films; for example, the plurality of gate driving circuits 10 may be located in the first conductive layer, the second conductive layer and the first source-drain metal layer.

At least a portion of the gate driving circuits 10 are located in at least one corner region of the bezel region BB and between the power supply auxiliary line L11 and the first power supply line VSS.

The at least one initial signal supply line Vinit is located between the plurality of gate driving circuits 10 and the power supply auxiliary line L11 in a corner region of the bezel region BB where the power supply auxiliary line L11 is located, or, as shown in FIG. 11, an orthographic projection of the at least one initial signal supply line Vinit on the base substrate is at least partially overlapped with orthographic projections of the plurality of gate driving circuits 10 on the base substrate.

FIG. 12 is a schematic diagram of a planar structure of a second source-drain metal layer in FIG. 11. In a structure shown in FIG. 11 and FIG. 12, an orthographic projection of the initial signal supply line Vinit on the base substrate is at least partially overlapped with orthographic projections of the plurality of gate driving circuits 10 on the base substrate, an area of the bezel region BB occupied by the initial signal supply line Vinit may be reduced, the bezel may be reduced or a width of the first power supply line VSS may be increased.

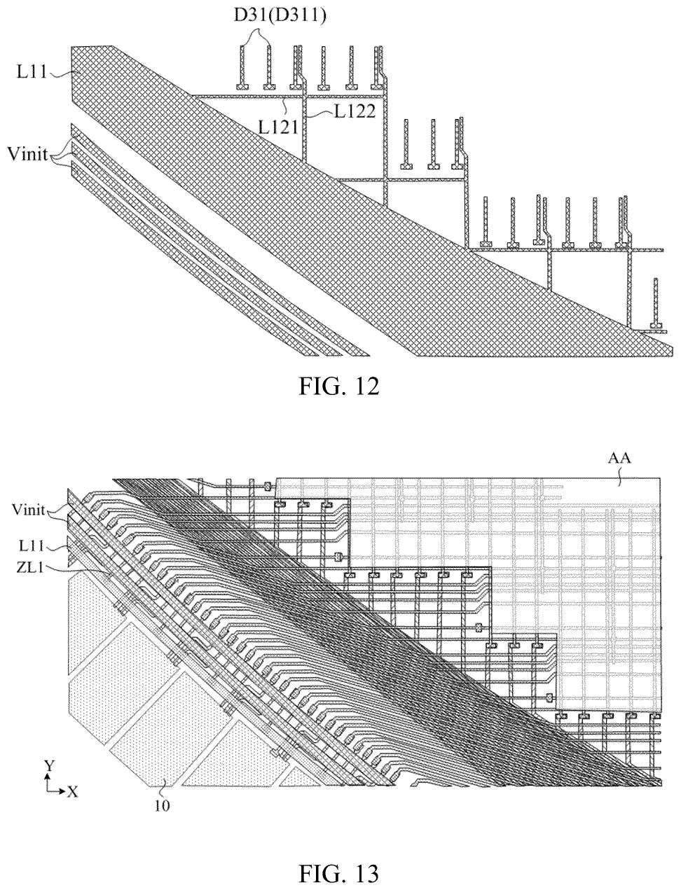

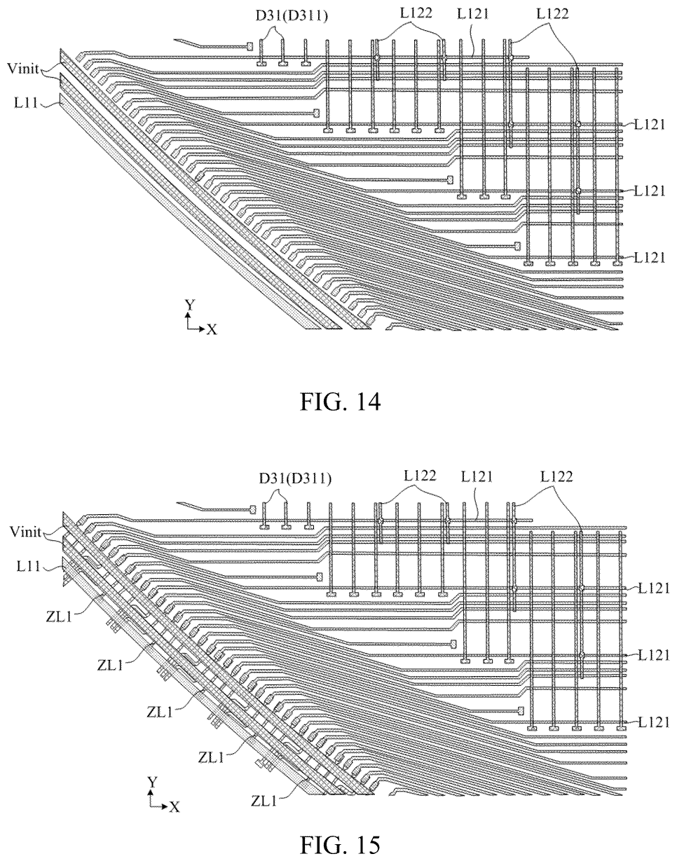

In an exemplary embodiment, as shown in FIGS. 13 and 14, FIG. 13 is a schematic diagram of structures of a first corner region C1 of the bezel region BB and a corresponding corner region of the display region, FIG. 14 is a schematic diagram of planar structures of a first source-drain metal layer and a second source-drain metal layer in FIG. 13, and the power supply auxiliary line L11 may be electrically connected to at least a portion of the first power supply connection lines L121.

The at least a portion of the first power supply connection lines L121 extend in the first direction X and extend from at least one corner region of the bezel region BB where the power supply auxiliary line L11 is located to at least one corresponding corner region of the display region AA.

At least a portion of the second power supply connection lines L122 are located in the display region AA and extend in the second direction Y. The at least a portion of the first power supply connection lines L121 and the at least a portion of the second power supply connection lines L122 form a mesh structure in at least one corner region of the display region AA.

In an exemplary embodiment, the display substrate may include a base substrate and a first conductive layer, a second conductive layer, a first source-drain metal layer, and a second source-drain metal layer stacked on the base substrate sequentially in a direction perpendicular to a plane where the display substrate is located; a plurality of first power supply connection lines L121 are located in the first source-drain metal layer, a plurality of second power supply connection lines L122 are located in the second source-drain metal layer, and a first power supply line is located at a side of the power supply auxiliary line L11 away from the display region AA; the first power supply line VSS is of a single-layer structure located in the first source-drain metal layer or the second source-drain metal layer, or the first power supply line VSS is of a double-layer structure located in the first source-drain metal layer and the second source-drain metal layer.

In an exemplary embodiment, as shown in FIGS. 13 and 14, the display substrate may further include at least one initial signal supply line Vinit.

The at least one initial signal supply line Vinit is located in the bezel region BB, and in a corner region of the bezel region BB where the power supply auxiliary line L11 is located; and at least one initial signal supply line Vinit is located between the power supply auxiliary line L11 and the display region AA.

In an exemplary embodiment, as shown in FIG. 13, the display substrate may further include a plurality of gate driving circuits 10 located in the first conductive layer, the second conductive layer and the first source-drain metal layer; at least a portion of the gate driving circuits 10 are located in at least one corner region of the bezel region BB and at a side of the power supply auxiliary line L11 away from the at least one initial signal supply line Vinit.

In an exemplary embodiment, in a structure as shown in FIGS. 13 and 14, the at least one initial signal supply line Vinit and the power supply auxiliary line L11 are located in one of the first source-drain metal layer and the second source-drain metal layer; or the at least one initial signal supply line Vinit and the power supply auxiliary line L11 are of a double-layer structure located in the first source-drain metal layer and the second source-drain metal layer; or one of the at least one initial signal supply line Vinit and the power supply auxiliary line L11 is located in one of the first source-drain metal layer and the second source-drain metal layer, and the other is of a double-layer structure located in the first source-drain metal layer and the second source-drain metal layer.

The at least one initial signal supply line Vinit and the power supply auxiliary line L11 are located between the plurality of gate driving circuits 10 and the display region AA in a corner region of the bezel region BB where the power supply auxiliary line L11 is located.

In an exemplary embodiment, in a structure shown in FIG. 13, the at least one initial signal supply line Vinit and the power supply auxiliary line L11 may be of a single-layer structure located in the second source-drain metal layer.

Orthographic projections of the at least one initial signal supply line Vinit and the power supply auxiliary line L11 on the base substrate are at least partially overlapped with orthographic projections of the plurality of gate driving circuits 10 on the base substrate.

In an exemplary embodiment, as shown in FIGS. 13 and 15, the display substrate may further include a plurality of first transfer connection electrodes ZL1 disposed in at least one film layer of the first conductive layer and the second conductive layer.

A plurality of first transfer connection electrodes ZL1 are located in at least one corner region of the bezel region BB where the power supply auxiliary line L11 is located, and are arranged along an extension direction of the power supply auxiliary line L11. One ends of the first transfer connection electrodes ZL1 are electrically connected with the power supply auxiliary line L11, and the other ends of the first transfer connection electrodes ZL1 are respectively electrically connected with the plurality of first power supply connection lines L121. FIG. 15 is a schematic diagram of a connection structure of the first transfer connection electrodes ZL1 to the power supply auxiliary line L11 and the first power supply connection lines L121 in FIG. 13.

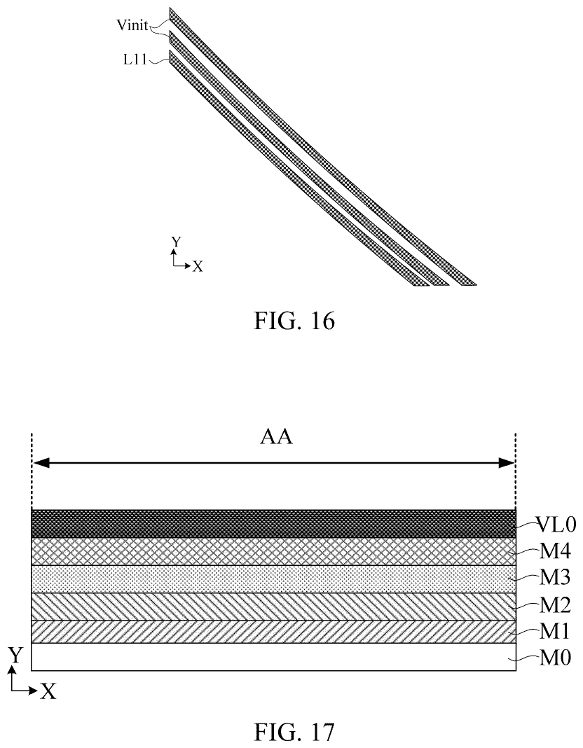

In an exemplary embodiment, the display substrate may further include a third source-drain metal layer, at least one of the at least one initial signal supply line Vinit and the power supply auxiliary line L11 is located in the third source-drain metal layer. As shown in FIG. 16, a schematic diagram of a planar structure of the third source-drain metal layer is shown, and a schematic diagram of a planar structure of the initial signal supply line Vinit and the power supply auxiliary line L11 provided in the third source-drain metal layer is shown.

In embodiments of the present disclosure, the initial signal supply line Vinit and the power supply auxiliary line L11 are arranged in at least two of the first source-drain metal layer, the second source-drain metal layer and the third source-drain metal layer, so that voltage drops of the initial signal supply line Vinit and the power supply auxiliary line L11 can be reduced, thereby improving the display effect. Where space permits, the initial signal supply line Vinit and the power supply auxiliary line L11 can be arranged in a multi-layer structure to reduce the voltage drop by a parallel structure. When the initial signal supply line Vinit and the power supply auxiliary line L11 are located in a plurality of films, the plurality of films can be directly contacted to form corresponding initial signal supply line Vinit and power supply auxiliary line L11.

In an exemplary embodiment, a quantity of initial signal supply lines Vinit may be set according to actual needs, for example, the quantity of initial signal supply lines Vinit is two or three.

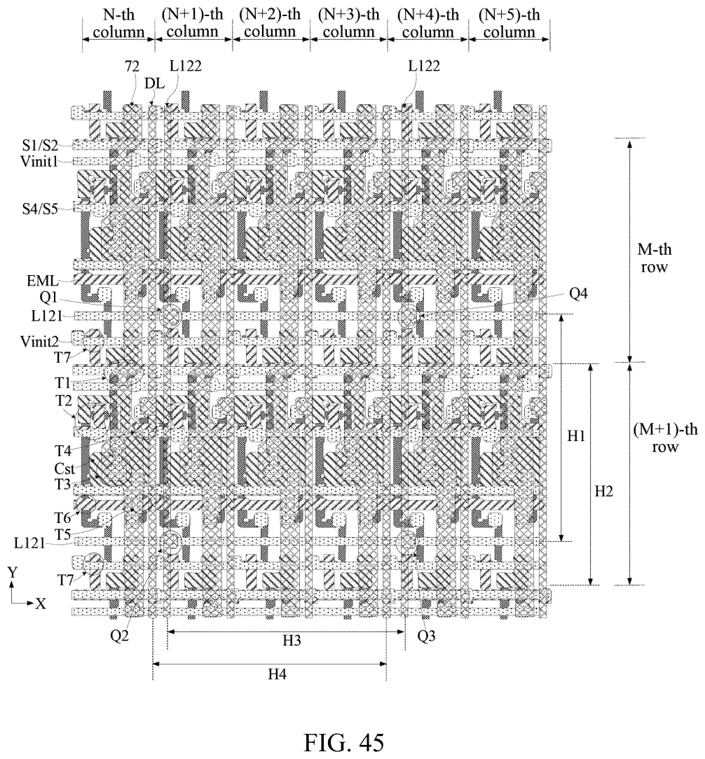

In an exemplary embodiment, as shown in FIGS. 7b and 45, at least a portion of the first power supply connection lines L121 may extend to a non-corner region of the display region AA in the first direction X, and at least a portion of the second power supply connection lines L122 may extend to a non-corner region of the display region AA in the second direction Y.

In an exemplary embodiment, as shown in FIGS. 7b and 45, at least a portion of the first power supply connection lines L121 can penetrate through the display region AA in the first direction X and extend from one of corner regions of the display region AA in the first direction X to a corner region AA on an opposite side of the display region AA; at least a portion of the second power supply connection lines L122 penetrate through the display regions AA in the second direction Y and extend from one of corner regions of the display region AA to a corner region on an opposite side of the display region AA in the second direction Y.

In an exemplary embodiment, the first power supply connection lines L121 can penetrate through the display region AA in the first direction X, it means that the first power supply connection lines L121 extending from one of corner regions of the display region AA to a corner region on an opposite side of the display region AA in the first direction X are continuous and unbroken; the second power supply connection lines L122 penetrate through the display region AA in the second direction Y, and it means that the second power supply connection lines L122 extending from one of corner regions of the display region AA to a corner region on an opposite side of the display region AA in the second direction Y are continuous and unbroken.

In an exemplary embodiment, as shown in FIGS. 6a to 8, 11 and 13, a boundary of at least one corner region of the display region AA and at least one corresponding corner region of the bezel region BB are all in a shape of an arc. In at least one corner region of the bezel region BB, the power supply auxiliary line L11, the at least one initial signal supply line Vinit and the first power supply line are all in a shape of an arc consistent with a shape of a corner region of the bezel region BB where they are located, and the power supply auxiliary line L11 and the first power supply line VSS are an integrally formed structure.

In an exemplary embodiment, as shown in FIGS. 6a to 8, 11 and 13, the display region AA includes a plurality of sub-pixels arranged in a plurality of arrays, and in the second direction Y, a pitch H1 between two adjacent first power supply connection lines L121 is consistent with a width H2 of one sub-pixel row along the second direction Y; in the first direction X, a pitch H3 between two adjacent second power supply connection lines L122 is consistent with a width of at least one sub-pixel column along the first direction X. For example, the pitch H3 between two adjacent second power supply connection lines L122 may be consistent with a width H4 of three sub-pixel columns in the first direction X.

In an exemplary embodiment, as shown in FIG. 8, a plurality of sub-pixels may form a plurality of pixels arranged in an array, each pixel may include at least three sub-pixels, a width of a pixel row in the second direction Y is consistent with a width H2 of a sub-pixel row in the second direction Y, a pixel column may include at least three sub-pixel columns, and a pitch H3 between two adjacent second power supply connection lines L122 in the first direction X may be consistent with a width H4 of at least one pixel column in the first direction X.

In an exemplary embodiment, in a structure shown in FIG. 13, the plurality of first power supply connection lines L121 may be disposed between two adjacent pixel rows and the plurality of second power supply connection lines L122 may be disposed between two adjacent pixel columns.

In an exemplary embodiment, as shown in FIG. 17, the display substrate may further include a common electrode layer VL0, which may be located on a side of the second source-drain metal layer away from the base substrate, and at least a portion of the power supply connection lines L12 are electrically connected to the common electrode layer VL0. In FIG. 17, M0 is a base substrate, M1 is a first conductive layer, M2 is a second conductive layer, M3 is a first source-drain metal layer, and M4 is a second source-drain metal layer.

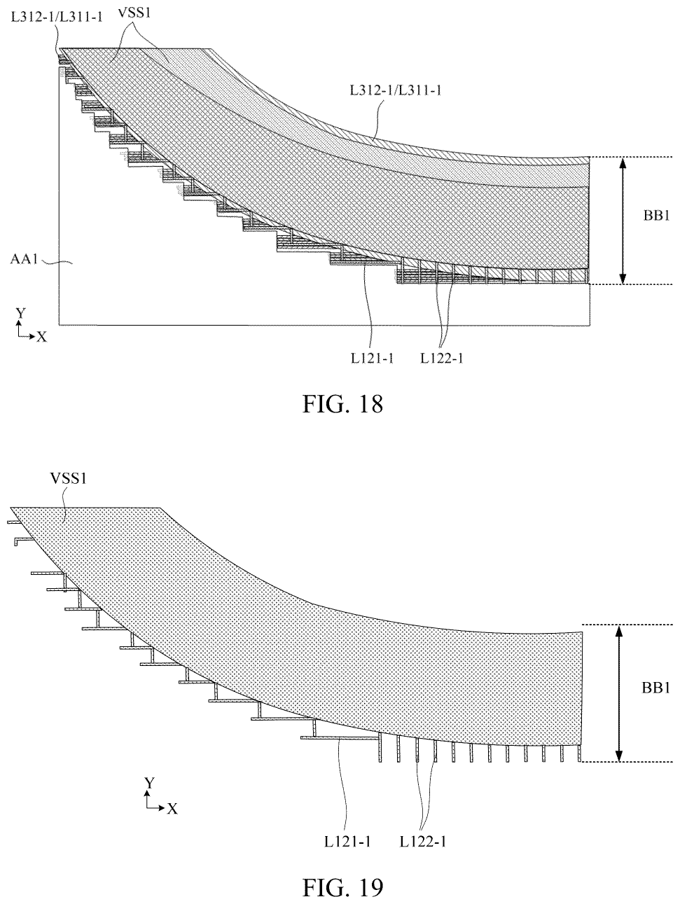

In an exemplary embodiment, as shown in FIGS. 18 and 19, the display substrate may further include a special-shaped display region AA1 and a special-shaped bezel region BB1.

A special-shaped region power supply line VSS1 located in the special-shaped bezel region BB1 and arranged in at least one film of the first source-drain metal layer and the second source-drain metal layer.

A plurality of special-shaped region second power supply connection lines L122-1, extending from the special-shaped bezel region BB to the special-shaped display region AA1, arranged in the first source-drain metal layer, and at least a portion of the special-shaped region second power supply connection lines L122-1 are electrically connected with the special-shaped region power supply line VSS1.

In an exemplary embodiment, as shown in FIGS. 18 and 19, FIG. 19 is a schematic diagram of a planar structure of a first source-drain metal layer in a structure shown in FIG. 18, and the display substrate may further include a plurality of special-shaped region first power supply connection lines L121-1.

A plurality of special-shaped region first power supply connection lines L121-1, located in the special-shaped bezel region BB1 and arranged in the first source-drain metal layer. At least a portion of the special-shaped region first power supply connection lines L121-1 are electrically connected with the special-shaped region power supply line VSS1 and at least a portion of the special-shaped region second power supply connection lines L122-1. An extension direction of the plurality of special-shaped region first power supply connection lines L121-1 intersects an extension direction of the plurality of special-shaped region second power supply connection lines L122-1. The special-shaped region power supply line VSS1, at least a portion of the special-shaped region first power supply connection lines L121-1 and at least a portion of the special-shaped region second power supply connection lines L122-1 form a mesh structure in the special-shaped bezel region.

In an exemplary embodiment, as shown in FIGS. 18 and 20, FIG. 20 is a schematic diagram of planar structures of the first conductive layer and the second conductive layer in FIG. 18, and the display substrate may further include a plurality of special-shaped region first signal connection lines L311-1 and a plurality of special-shaped region second signal connection lines L312-1.

The plurality of special-shaped region first signal connection lines L311-1 and the plurality of special-shaped region second signal connection lines L312-1 are located in the special-shaped bezel region BB1, the plurality of special-shaped region first signal connection lines L311-1 are arranged in the first conductive layer, and the plurality of special-shaped region second signal connection lines L312-1 are arranged in the second conductive layer.

The plurality of special-shaped region first signal connection lines L311-1 and the plurality of special-shaped region second signal connection lines L312-1 are alternately arranged in a direction away from the display region AA.

Orthographic projections of at least a portion of the special-shaped region first signal connection lines L311-1 and at least a portion of the special-shaped region second signal connection lines L312-1 on the base substrate at least partially overlaps an orthographic projection of the special-shaped region power supply line on the base substrate.

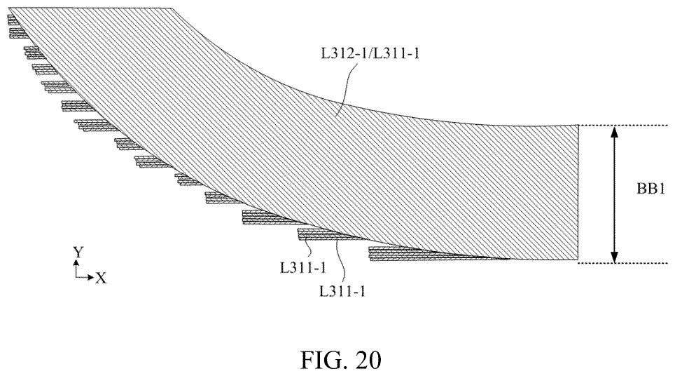

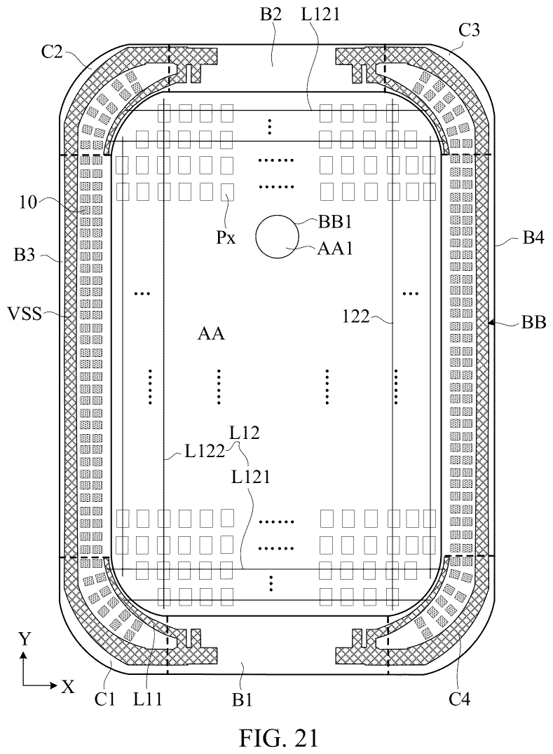

In an exemplary embodiment, the special-shaped display region AA1 may be at the position of the camera and the bangs of the bangs screen in the display substrate. As shown in FIG. 21, the special-shaped display region AA1 may be at the position of the camera.

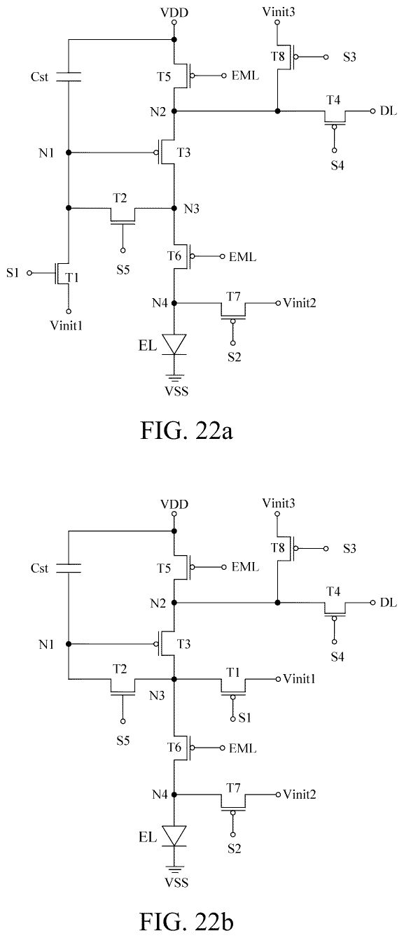

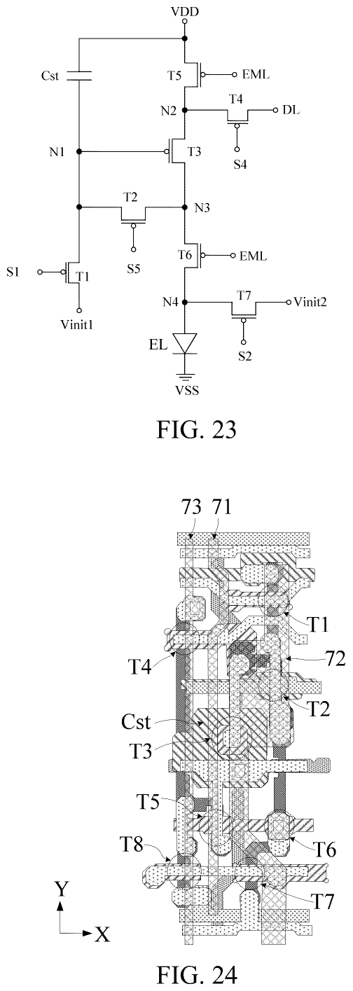

In an exemplary embodiment, in the above-described structures shown in FIGS. 6 to 8, 11 and 13, a sub-pixel Px in the display region AA may include a pixel driving circuit, and a circuit schematic diagram of the pixel driving circuit may be shown in FIGS. 4, 22a to 23, wherein the pixel driving circuit shown in FIGS. 22a and 22b may be applied to the structures shown in FIGS. 8 and 11, and the pixel driving circuit shown in FIGS. 4 and 23 may be applied to the structures shown in FIGS. 8, 11 and 13. In an exemplary embodiment, the circuit schematic diagrams shown in FIGS. 22a and 22b can be applied to a structure shown in FIG. 13 in the case where an initial signal supply line Vinit is added to a structure shown in FIG. 13.

The circuit schematic diagram shown in FIG. 22a differs from the circuit schematic diagram shown in FIG. 4 in that an eighth transistor T8 and a third initial signal supply line Vinit are added on the basis of the circuit schematic diagram shown in FIG. 4. In an exemplary embodiment, the first transistor T1 and the second transistor T2 in FIG. 22a may be N-type transistors (i.e., oxide thin film transistors), and the third transistor T3 to the eighth transistor T8 may be P-type transistors (Low Temperature Poly-Silicon, LTPS for short); The pixel driving circuit of FIG. 22b differs from the pixel driving circuit of FIG. 4 in that the second transistor T2 in FIG. 22b may be an N-type transistor (i.e. an oxide thin film transistor), the first transistor T1, the third transistor T3 to the eighth transistor T8 may be P-type transistors (Low Temperature Poly-Silicon, LTPS for short), and a second electrode of the first transistor T1 is electrically connected to a second electrode of the third transistor T3 and a second electrode of the second transistor T2. In FIGS. 22a and 22b, a low temperature polysilicon thin film transistor and an oxide thin film transistor are integrated on the display substrate to form a Low Temperature Polycrystalline Oxide (LTPO for short) display substrate.

In an exemplary embodiment, a schematic diagram of a circuit structure of the circuit schematic diagram shown in FIG. 22b may be as shown in FIGS. 24 to 34B. In FIG. 24, the second transistor T2 is an N-type transistor (i.e., an oxide thin film transistor), and the first transistor T1, the third transistor T3 to the eighth transistor T8 are P-type transistors (Low Temperature Poly-Silicon, LTPS for short). As shown in FIG. 24, the pixel driving circuit may include a first transistor T1 to an eighth transistor T8 and a storage capacitor Cst; in the second direction Y, the fourth transistor T4 and the fifth transistor T5 are located on two sides of the third transistor T3, the second transistor T2 and the sixth transistor T6 are located on two sides of the third transistor T3, the second transistor T2 is located between the first transistor T1 and the sixth transistor T6, and the fourth transistor T4, the first transistor T1 and the second transistor T2 are located at a same side of the third transistor T3, the fifth transistor T5 and the sixth transistor T6 are located at a same side of the third transistor T3, the eighth transistor T8 is located at a side of the fifth transistor T5 away from the third transistor T3, and the seventh transistor T7 is located at a side of the sixth transistor T6 away from the second transistor T2; in the first direction X, the fourth transistor T4, the fifth transistor T4, and the eighth transistor T8 are located at a same side of the third transistor T3, and the first transistor T1, the second transistor T2, the sixth transistor T6, and the seventh transistor T7 are located at the other side of the third transistor T3.

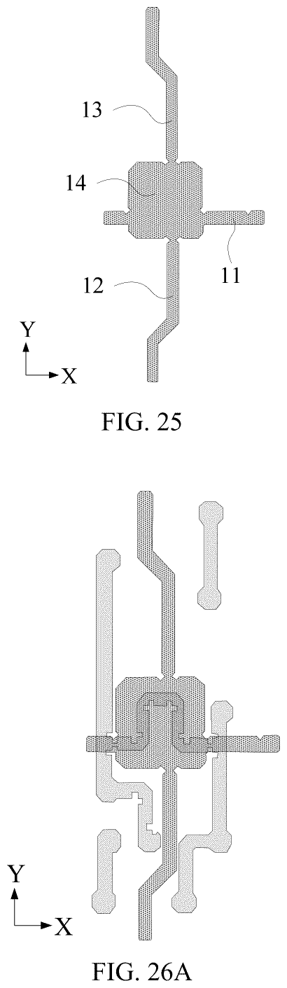

FIG. 25 is a schematic diagram of a planar structure after a pattern of a shielding layer in the pixel driving circuit is formed on the base substrate. In an exemplary embodiment, the pattern of the shielding layer may include a first shielding structure 11, a second shielding structure 12, a third shielding structure 13 and a shielding block 14. A shape of the shielding block 14 may be rectangle, and the corners of the rectangular may be chamfered. The first shielding structure 11 may be in a shape of a strip extending in the first direction X, and the first shielding structure 11 is disposed at a side of the shielding block 14 in the first direction X and connected to the shielding block 14. The second shielding structure 12 may be a strip shape extending along the second direction Y and the second shielding structure 12 is disposed on a side of the shielding block 14 in the second direction Y and connected with the shielding block 14. The third shielding structure 13 may be in a shape of a bend line extending along the second direction Y and the third shielding structure 13 is disposed on a side of the shielding block 14 in a direction opposite to the second direction Y and connected with the shielding block 14. In an exemplary implementation, the first shielding structure 11 of each pixel drive circuit is connected to the shielding blocks 14 of adjacent pixel drive circuits in the first direction X such that the shielding layers in a pixel drive circuit row are connected as a whole to form an interconnected integral structure. In an exemplary implementation, the second shielding structure 12 of each pixel drive circuit is connected to the third shielding structures 13 of adjacent pixel drive circuits in the second direction Y such that the shielding layers in a pixel drive circuit column are connected as a whole to form an interconnected integral structure. In an exemplary implementation, the shielding layers in a pixel drive circuit row and a pixel drive circuit column are connected as a whole, which may ensure that the shielding layers in the display substrate have a same potential, and this is beneficial to improving uniformity of a panel, avoiding display defect of the display substrate, and ensuring a display effect of the display substrate.

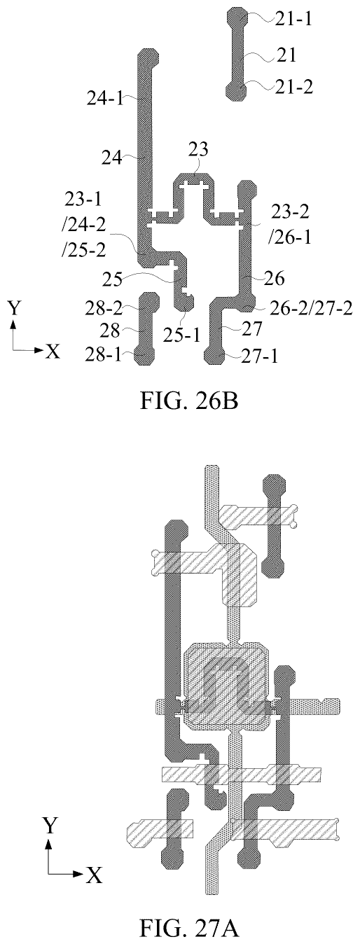

FIG. 26A is a schematic diagram of a planar structure after a first semiconductor layer is formed in the pixel driving circuit, and FIG. 26B is a schematic diagram of a planar structure of the first semiconductor layer in the pixel driving circuit; as shown in FIG. 26B, the first semiconductor layer may include an active layer 21 of the first transistor T1, an active layer 23 of the third transistor T3 to an active layer 28 of the eighth transistor T8, and the active layer 23 of the third transistor T3 to the active layer 27 of the seventh transistor T7 are of an interconnected integral structure. In an exemplary embodiment, in the first direction X, an active layer 24 of the fourth transistor T4 and an active layer 25 of the fifth transistor T5 are located at a same side of the active layer 23 of the third transistor T3, and an active layer 26 of the sixth transistor T6 and the active layer of the seventh transistor T7 are located at the other side of the active layer 23 of the third transistor T3; in the second direction Y, the active layer 24 of the fourth transistor T4 and the active layer 25 of the fifth transistor T5 are located at two sides of the active layer 23 of the third transistor T3, and the active layer 25 of the fifth transistor T5, the active layer 26 of the sixth transistor T6, the active layer 27 of the seventh transistor T7 and the active layer 28 of the eighth transistor T8 are located at a same side of the active layer 23 of the third transistor T3, and the active layer 27 of the seventh transistor T7 is located at a side of the active layer 26 of the sixth transistor T6 away from the active layer 23 of the third transistor T3; in the first direction X, the active layer 28 of the eighth transistor T8 is located at a side of the active layer 25 of the fifth transistor T5 away from the active layer 27 of the seventh transistor T7; in the second direction Y, the active layer of the first transistor T1 is located at a side of the third transistor away from the active layer 27 of the seventh transistor T7, and in the first direction X, the active layer 21 of the first transistor T1 is located at a side of the active layer of the third transistor T3 away from the active layer 24 of the fourth transistor T4. In an exemplary embodiment, a shape of the active layer 23 of the third transistor T3 may be an inverted “Ω” shape and a shape of the active layer 24 of the fourth transistor T4 to the active layer 28 of the eighth transistor T8 may be an “I” shape. In an exemplary embodiment, an active layer of each transistor may include a first region, a second region, and a channel region located between the first region and the second region. In an exemplary embodiment, the first region 23-1 of the active layer 23 of the third transistor T3 may simultaneously serve as the second region 25-2 of the active layer 25 of the fifth transistor T5 and the second region 24-2 of the active layer 24 of the fourth transistor T4, the second region 23-2 of the active layer 23 of the third transistor T3 may simultaneously serve as the first region 26-1 of the active layer 26 of the sixth transistor T6, the second region 26-2 of the active layer 26 of the sixth transistor T6 may simultaneously serve as the second region 27-2 of the active layer 27 of the seventh transistor T7, the first region 28-1 and the second region 28-2 of the active layer 28 of the eighth transistor T8 may be individually provided, the first region 21-1 and the second region 21-2 of the active layer 21 of the first transistor T1 may be individually provided, the first region 24-1 of the active layer 24 of the fourth transistor T4, the first region 25-1 of the active layer 25 of the fifth transistor T5 and the first region 27-1 of the active layer 27 of the seventh transistor T7 may be individually provided. In an exemplary implementation, an orthographic projection of the active layer 23 of the third transistor T3 on the substrate is at least partially overlapped with an orthographic projection of the shielding block 14 on the substrate. In an exemplary implementation, an orthographic projection of the channel region of the active layer 23 of the third transistor T3 on the substrate is within the range of the orthographic projection of the shielding block 14 on the substrate. In an exemplary embodiment, the first semiconductor layer may be made of poly-crystalline silicon (p-Si), i.e., the first transistor T1, the third transistor T3 to the eighth transistor T8 are LTPS thin film transistors.

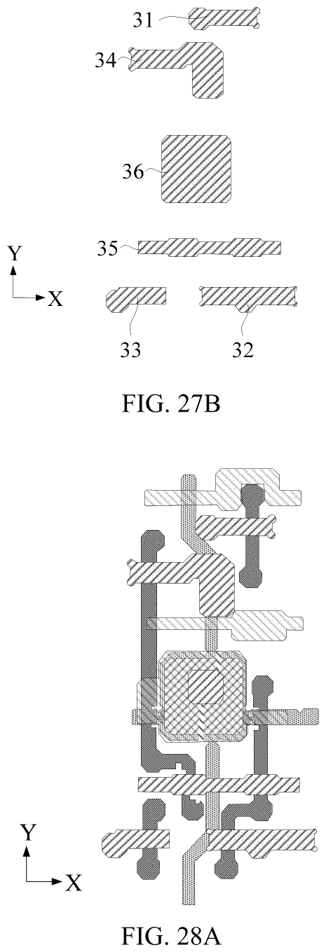

FIG. 27A is a schematic diagram of a planar structure after a first conductive layer is formed in the pixel driving circuit, and FIG. 27B is a schematic diagram of a planar structure of the first conductive layer in the pixel driving circuit; as shown in FIG. 27B, the pattern of the first conductive layer may include at least: a control electrode 31 of the first transistor T1, a control electrode 32 of the seventh transistor T7, a control electrode 33 of the eighth transistor T8, a control electrode 34 of the fourth transistor T4, a light emitting control line 35, and a first electrode plate 36 of the storage capacitor. Main body portions of the control electrode 31 of the first transistor T1, the control electrode 32 of the seventh transistor T7, the control electrode 33 of the eighth transistor T8 may have a structure of a strip that extends along the first direction X, the control electrode 34 of the fourth transistor T4 may have a shape of an “L”. In a same pixel driving circuit, the control electrode 31 of the first transistor T1, the control electrode 34 of the fourth transistor T4, and the first electrode plate 36 of the storage capacitor, the light emitting control line 35 may be arranged in an opposite direction of the second direction Y, the control electrode 32 of the seventh transistor T7 and the control electrode 33 of the eighth transistor T8 may be arranged in the first direction X, and in the second direction Y, the control electrode 32 of the seventh transistor T7 and the control electrode 33 of the eighth transistor T8 are located at a side of the light emitting control lines 35 away from the first electrode plate 36 of the storage capacitor. In an exemplary embodiment, the first electrode plate 36 may be located between the light emitting control line 35 and the control electrode 34 of the fourth transistor T4, the first electrode plate 33 may be in a rectangular shape, the corners of the rectangular may be chamfered, and an orthographic projection of the first electrode plate 36 on the base substrate is overlapped with an orthographic projection of the active layer of the third transistor T3 on the base substrate. In an exemplary embodiment, the first electrode plate 36 may simultaneously serve as a plate of the storage capacitor and the control electrode of the third transistor T3. In an exemplary embodiment, a region where the light emitting control line 35 overlaps an active layer of the fifth transistor T5 serves as a control electrode of the fifth transistor T5, and a region where the light emitting control line 35 overlaps an active layer of the sixth transistor T6 serves as a control electrode of the sixth transistor T6.

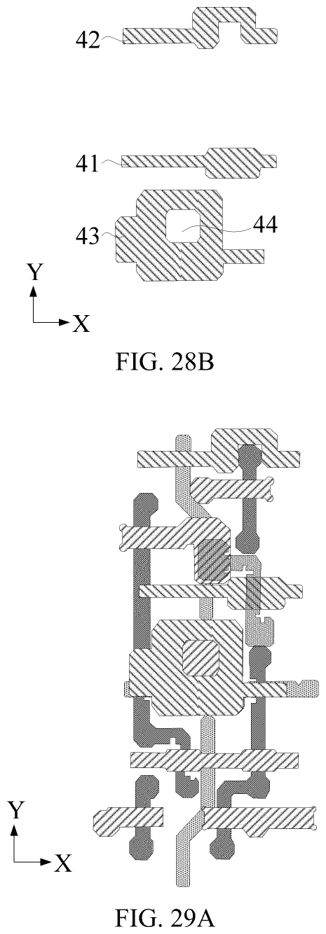

FIG. 28A is a schematic diagram of a planar structure after a second conductive layer is formed in the pixel driving circuit, and FIG. 28B is a schematic diagram of a planar structure of the second conductive layer in the pixel driving circuit; as shown in FIG. 28B, the pattern of the second conductive layer includes at least a first shielding line 41, a first initial signal line 42, and a second electrode plate 43 of the storage capacitor, main body portions of the first shielding line 41 and the first initial signal line 42 may extend along the first direction X. The second electrode plate 43 of the storage capacitor serves as the other plate of the storage capacitor. In the second direction Y, the first shielding line 41 is located between the first initial signal line 42 and the second electrode plate 44. For example, the first initial signal line 42, the first shielding line 41, and the second electrode plate 43 of the storage capacitor are arranged sequentially along the second direction Y. In an exemplary embodiment, the first shielding line 41 is configured as a shielding layer of the second transistor T2 to shield a channel of the second transistor T2 and ensure electrical performance of the oxide second transistor T2. In an exemplary implementation, a profile of the second electrode plate 43 may be in a shape of a rectangle whose corners may be chamfered, there is an overlapping area between an orthographic projection of the second electrode plate 43 on the substrate and an orthographic projection of the first electrode plate 36 on the substrate, and the first electrode plate 36 and the second electrode plate 43 form the storage capacitor Cst of the pixel drive circuit. The second electrode plate 43 is provided with an opening 44, and the opening 44 may be located in the middle of the second electrode plate 43. The opening 44 may be rectangular and enables the second electrode plate 43 to form an annular structure. An orthographic projection of the first electrode plate 36 on the base substrate includes an orthographic projection of the opening 44 on the base substrate. In an exemplary embodiment, the opening 44 is configured to accommodate a first via subsequently formed, the first via is located in the opening 44 and exposes the first electrode plate 36, so that a second electrode of the first transistor T1 subsequently formed is connected with the first electrode plate 36. In an exemplary embodiment, signals of the first shielding line 41 and a fifth scan signal line 51 subsequently formed may be the same, i.e., the first shielding line 41 and the fifth scan signal line 51 subsequently formed are connected in parallel, and are connected with a same signal source, so that the first shielding line 41 may serve as a bottom gate electrode (i.e., a bottom control electrode) of the first transistor T1. In an exemplary embodiment, the first shielding line 41 is configured as a shielding layer of the second transistor T2 to shield a channel of the second transistor T2 and ensure electrical performance of the oxide second transistor T2.

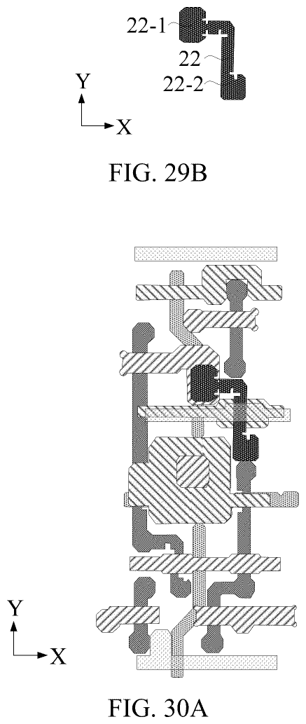

FIG. 29A is a schematic diagram of a planar structure after a second semiconductor layer is formed in the pixel driving circuit, and FIG. 29B is a schematic diagram of a planar structure of the second semiconductor layer in the pixel driving circuit; as shown in FIG. 29B, the pattern of the second semiconductor layer includes at least that an active layer 22 of the second transistor T2 may be in a shape of an “L”. The first region 22-1 and the second region 22-2 of the active layer 22 of the second transistor T2 may be separately disposed. In the second direction Y, the active layer 22 of the second transistor T2 may be located between the active layer 21 of the first transistor T1 and the active layer 26 of the sixth transistor T6, and in the first direction X, the active layer of the second transistor T2 may be located at a side of the active layer 23 of the third transistor T3 away from the active layer 24 of the fourth transistor T4. In an exemplary embodiment, the second semiconductor layer may be made of an oxide, i.e., the second transistor T2 is an oxide thin film transistor.

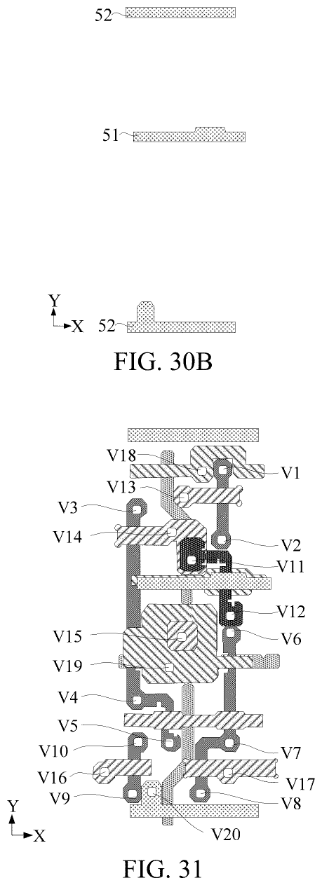

FIG. 30A is a schematic diagram of a planar structure after a third conductive layer is formed in the pixel driving circuit, and FIG. 30B is a schematic diagram of a planar structure of the third conductive layer in the pixel driving circuit; as shown in FIG. 30B, the pattern of the third conductive layer may include at least a fifth scan signal line 51 and a third initial signal line 52, main body portions of the fifth scan signal line 51 and the third initial signal line 52 may extend along the first direction X, and the fifth scan signal line 51 and the third initial signal line 52 are sequentially arranged along the second direction Y. In an exemplary embodiment, a region where the fifth scan signal line 51 overlaps the active layer 22 of the second transistor T2 serves as a control electrode of the second transistor T2.

FIG. 31 is a schematic diagram of a planar structure in which a pattern of a sixth insulating layer is formed in the pixel driving circuit; the pattern of the sixth insulating layer includes at least a first via V1 to a twentieth via V20. The sixth insulating layer, the fifth insulating layer, the fourth insulating layer, the third insulating layer and the second insulating layer in the first via V1 to the tenth via V10 are etched away, the sixth insulating layer and the fifth insulating layer in the eleventh via V11 to the twelfth via V12 are etched away, the sixth insulating layer, the fifth insulating layer, the fourth insulating layer and the third insulating layer in the thirteenth via V13 to the seventeenth via V17 are etched away, the sixth insulating layer, the fifth insulating layer and the fourth insulating layer in the eighteenth via V18 to the nineteenth via V19 are etched away, and the sixth insulating layer in the twentieth via V20 is etched away. In an exemplary embodiment, the first via V1 and the second via expose surfaces of the first and second regions of the active layer 21 of the first transistor T1, respectively, the third via V3 and the fourth via V4 expose surfaces of the first region and the second region of the active layer of the fourth transistor T4, respectively, the fifth via V5 exposes a surface of the first region of the active layer of the fifth transistor T5, the sixth via V6 and the seventh via V7 expose surfaces of the first region and the second region of the active layer of the sixth transistor T6, respectively, the eighth via V8 exposes a surface of the first region of the seventh transistor T7, the ninth via V9 and the tenth via V10 expose surfaces of the first region and the second region of the active layer of the eighth transistor T8, respectively, the eleventh via V11 and the twelfth via V12 expose surfaces of the first region and the second region of the second transistor T2, respectively, the thirteenth via V13 exposes a surface of the control electrode 31 of the first transistor T1, the fourteenth via V14 exposes a surface of the control electrode 34 of the fourth transistor T4, the fifteenth via V15 exposes a surface of the first electrode plate 36 of the storage capacitor, the seventeenth and eighteenth vias V17 and V18 expose surfaces of a control electrode 32 of the seventh transistor T7 and a control electrode 33 of the eighth transistor T8, respectively, the nineteenth via V19 exposes a surface of the second electrode plate 43 of the storage capacitor, and the twentieth via V20 exposes a surface of the third initial signal line 52.

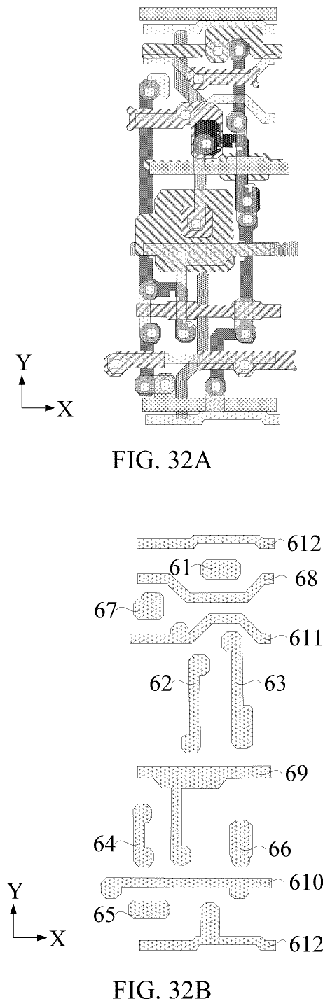

FIG. 32A is a schematic diagram of a planar structure after a first source-drain metal layer is formed in the pixel driving circuit, and FIG. 32B is a schematic diagram of a planar structure of the first source-drain metal layer in the pixel driving circuit; as shown in FIG. 32B, the first source-drain metal layer may include a first connection electrode 61, a second connection electrode 62, a third connection electrode 63, a fourth connection electrode 64, a fifth connection electrode 65, a sixth connection electrode 66, a seventh connection electrode 67, a first scan signal line 68 (i.e. S1 in FIG. 22b), a ninth connection electrode 69, a second scan signal line 610 (i.e. S2 and S3 share one scan signal line in FIG. 22b), a fourth scan signal line 611 (i.e. S4 in FIG. 22b), and a second initial signal line 612 (i.e. Vinit2 in FIG. 22b).

The first connection electrode 61 is electrically connected to the first region of the active layer of the first transistor T1 and the first initial signal line 42 through the first via V1 and the eighteenth via V18, respectively, the second connection electrode 62 are respectively connected to the first region of the active layer of the second transistor T2 and the first electrode plate 36 of the storage capacitor through the eleventh via V11 and the fifteenth via V15, the third connection electrode 63 is electrically connected to the second region of the active layer of the first transistor T1, the second region of the active layer of the second transistor T2, and the first region of the active layer of the sixth transistor T6 through the second via V2, the twelfth via V12, and the sixth via V6, respectively, the fourth connection electrode 64 is electrically connected to the second region of the active layer of the fifth transistor T5 and the second region of the active layer of the eighth transistor T8 through the fourth via V4 and the tenth via V10, respectively, the fifth connection electrode 65 is electrically connected to the first region of the active layer of the eighth transistor T8 and the third initial signal line 52 through the ninth via V9 and the twentieth via V20, respectively, the sixth connection electrode 66 is electrically connected to the second region of the active layer of the sixth transistor T6 through the seventh via V7, the seventh connection electrode 67 is electrically connected to the first region of the active layer of the fourth transistor T4 through the third via V3.

the first scan signal line 68 is electrically connected to the control electrode 31 of the first transistor T1 through the thirteenth via V13, the ninth connection electrode 69 is electrically connected to the first region of the active layer of the fifth transistor T5 and the second electrode plate 43 of the storage capacitor through the fifth via V5 and the nineteenth via V19, respectively, the second scan signal line 610 is electrically connected to the control electrode 32 of the seventh transistor T7 and the control electrode 33 of the eighth transistor T8 through the sixteenth via V16 and the seventeenth V17, respectively, the fourth scan signal line 611 is electrically connected to the control electrode 34 of the fourth transistor T4 through the fourteenth via V14, and the second initial signal line 612 is electrically connected to the first region of the active layer of the seventh transistor T7 through the eighth via V8.

In an exemplary embodiment, the first connection electrode 61 may serve as a first electrode of the first transistor T1, the second connection electrode 62 may serve as a second electrode of the second transistor T2, the third connection electrode 63 may serve as a second electrode of the first transistor T1, a first electrode of the sixth transistor T6, a second electrode of the second transistor T2, the fourth connection electrode 64 may serve as a second electrode of the fifth transistor T5, a second electrode of the fourth transistor T4, a first electrode of the third transistor T3, a second electrode of the eighth transistor T8, the fifth connection electrode 65 may serve as a first electrode of the eighth transistor T8, the sixth connection electrode 66 may serve as a second electrode of the sixth transistor T6, a second electrode of the seventh transistor T7, the seventh connection electrode 37 may serve as a first electrode of the fourth transistor T4, the first scan signal line 68 can serve as a connection line for control electrodes 31 of a plurality of first transistors T1 in a same sub-pixel row, and provide scan signals to the control electrodes 31 of the plurality of first transistors T1 located in the same sub-pixel row, the ninth connection electrode 69 may serve as a first electrode of the fifth transistor T5, the second scan signal line 610 may serve as a connection line for the control electrode 32 of the seventh transistor T7 and the control electrode 33 of the eighth transistor T8, the fourth scan signal line 611 may serve as a connection line for control electrodes 34 of a plurality of fourth transistors T4 located in a same sub-pixel row, and provide scan signals to the control electrodes 34 of the plurality of fourth transistors T4 located in the same sub-pixel row, the second initial signal line 612 may serve as a first electrode of the seventh transistor T7.

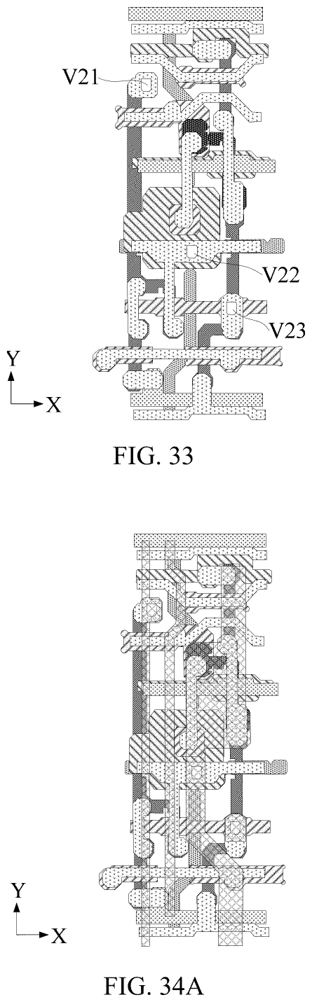

FIG. 33 is a schematic diagram of a planar structure in which patterns of a seventh insulating layer and a first planarization layer are formed in the pixel driving circuit; as shown in FIG. 33, a plurality of vias are provided on the seventh insulating layer and the first planarization layer, and the plurality of vias may include a twenty-first via V21 to a twenty-third via V23. The first planarization layer and the seventh insulating layer in the twenty-first via V21 are etched away to expose a surface of the seventh connection electrode 67, and the twenty-first via V21 is configured such that a data line formed subsequently is connected with the fourth connection electrode 67 through the via; the first planarization layer and the seventh insulating layer in the twenty-second via V22 are etched away to expose a surface of the ninth connection electrode 69, and the twenty-second via V22 is configured such that a second power supply line formed subsequently is connected with the ninth connection electrode 69 through the via; the first planarization layer and the seventh insulating layer in the twenty-third via V23 are etched away to expose a surface of the sixth connection electrode 66, and the twenty-third via V23 is configured such that an anode connection electrode formed subsequently is connected with the sixth connection electrode 66 through the via.

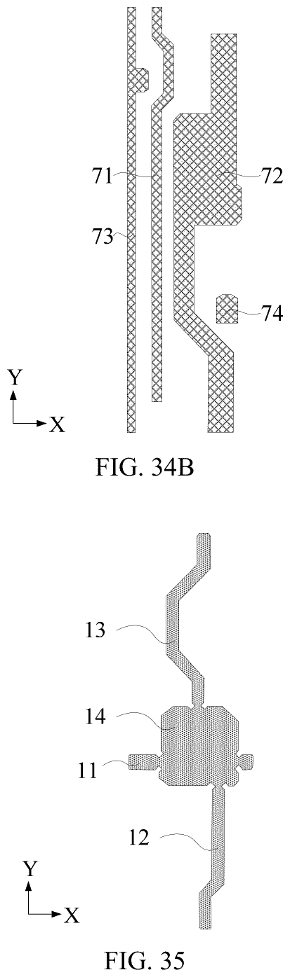

FIG. 34A is a schematic diagram of a planar structure after a second source-drain metal layer is formed in the pixel driving circuit, and FIG. 34B is a schematic diagram of a planar structure of the second source-drain metal layer in the pixel driving circuit. As shown in FIG. 34B, in the display region, the second source-drain metal layer includes at least a second power supply connection line 71 (which is electrically connected to the first power supply line VSS or the power supply auxiliary line L11 and provides a voltage signal of the second power supply line VSS to the pixel driving circuit, and the second power supply connection line 71 which extends to the corner region of the display region AA is equivalent to the above-described second power supply connection line L122 and is electrically connected to the power supply auxiliary line L11; the second power supply connection line 71 which does not extend to the corner region of the display region AA is electrically connected to the first power supply line VSS), a third power supply connection line 72 (which is electrically connected to the second power supply line VDD and provides a voltage signal of the second power supply line VDD to the pixel driving circuit), a data line 73 (that is, the above-mentioned D311) and an anode connection electrode 74. In an exemplary embodiment, the second power supply connection line 71, the third power supply connection line 72, and the data line 73 may be in a structure of bending line in which a main body portion extends in the first direction X, the power supply connection line 71 is located between the data line 73 and the third power supply connection line 72 in the first direction, for example, the data line 73, the power supply connection line 71, and the third power supply connection line 72 are sequentially arranged in the first direction X. The third power supply connection line 72 is electrically connected to the ninth connection electrode 69 (i.e., a first electrode of the fifth transistor T5) through the twenty-second via V22, the data line 73 is electrically connected to a first electrode of the fourth transistor T4 (i.e., the seventh connection electrode 67) through the twenty-first via V21, and the anode connection electrode 74 is electrically connected to a second electrode of the sixth transistor T6 (i.e., the sixth connection electrode 66) through the twenty-third via V23.

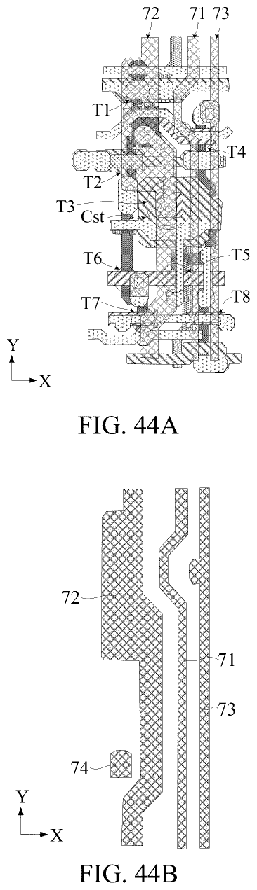

In an exemplary embodiment, a schematic diagram of a circuit structure of the circuit schematic diagram shown in FIG. 22a may be as shown in FIGS. 35 to 44B. As shown in FIG. 44A, the pixel driving circuit may include a first transistor T1 to an eighth transistor T8 and a storage capacitor Cst. The first transistor T1 and the second transistor T2 in FIG. 44A may be N-type transistors (i.e. oxide thin film transistors), and the third transistors T3 to the eighth transistors T8 may be P-type transistors (Low Temperature Poly-Silicon, LTPS for short). FIG. 44A differs from FIG. 24 in that, in the first direction X, the positions of the fourth transistor T4, the fifth transistor T5, and the eighth transistor T8 are interchanged with the positions of the first transistor T1, the second transistor T2, the sixth transistor T6, and the seventh transistor T7, and the first transistor T1 is an N-type transistor.

FIG. 35 is a schematic diagram of a planar structure after a pattern of a shielding layer in the pixel driving circuit is formed on the base substrate. The pattern of the shielding layer of FIG. 35 is similar in structure to the pattern of the shielding layer shown in FIG. 25 and will not be described in detail here.

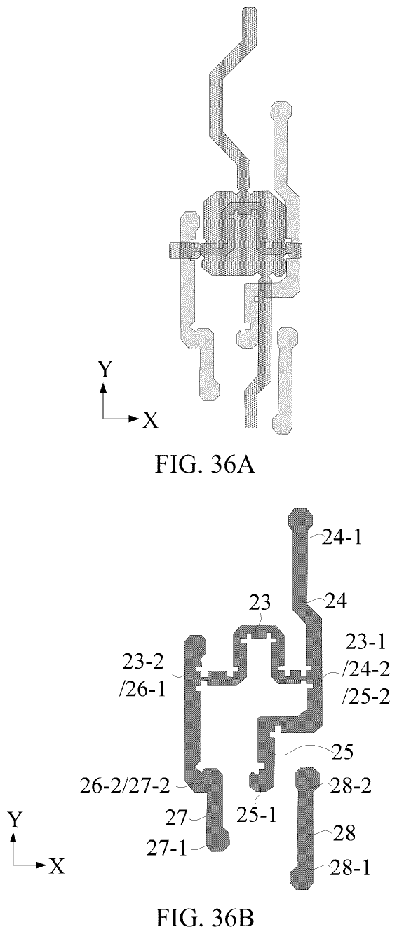

FIG. 36A is a schematic diagram of a planar structure after a first semiconductor layer is formed in the pixel driving circuit, and FIG. 36B is a schematic diagram of a planar structure of the first semiconductor layer in the pixel driving circuit; as shown in FIG. 36B, the pattern of the first semiconductor layer differs from that of FIG. 26B in that the active layer of the first transistor T1 is not provided in the first semiconductor layer, and in the first direction X, the positions of the active layer 26 of the sixth transistor T6 and the active layer of the seventh transistor T7 are interchanged with the positions of the active layer of the fourth transistor T4, the active layer of the fifth transistor T5, and the active layer of the eighth transistor T8. Other structural diagrams in FIG. 36B are similar to those of FIG. 26B and will not be described in detail herein.

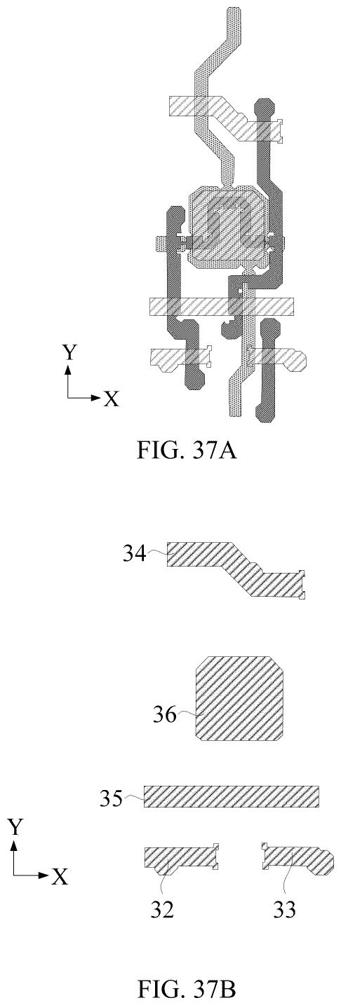

FIG. 37A is a schematic diagram of a planar structure after a first conductive layer is formed in the pixel driving circuit, and FIG. 37B is a schematic diagram of a planar structure of the first conductive layer in the pixel driving circuit; FIG. 37B differs from FIG. 27B in that the control electrode 31 of the first transistor T1 is not provided in the first conductive layer, and the positions of the control electrode 32 of the seventh transistor T7 and the control electrode 33 of the eighth transistor T8 are interchanged in the first direction X. Other structures in FIG. 37B are similar to those in FIG. 27B and will not be described in detail here.

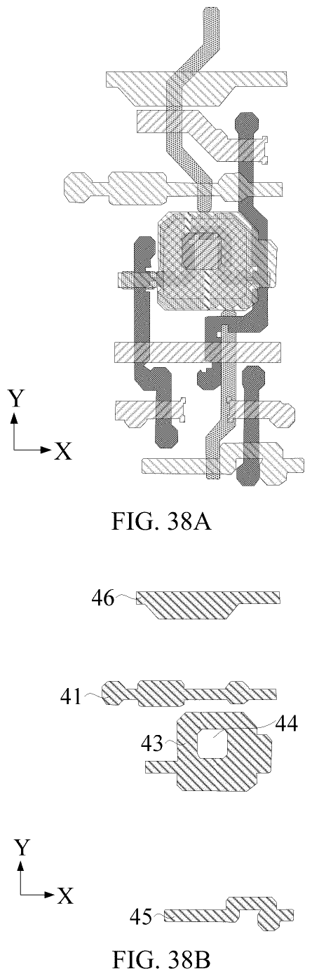

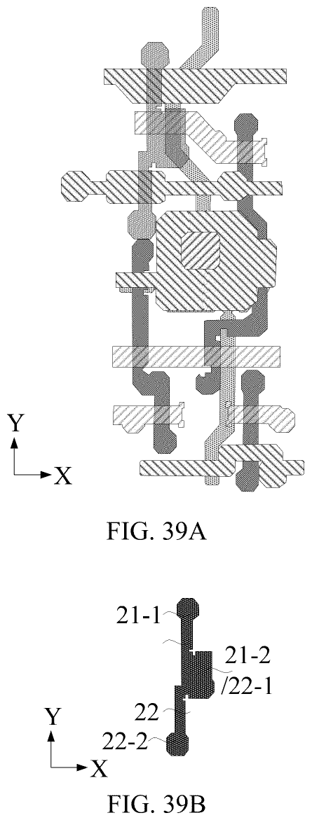

FIG. 38A is a schematic diagram of a planar structure after a second conductive layer is formed in the pixel driving circuit, and FIG. 38B is a schematic diagram of a planar structure of the second conductive layer in the pixel driving circuit; FIG. 38B differs from FIG. 28B in that the first initial signal line 42 is not provided, and in the second direction Y, a second shielding line 46 is provided at a side of the first shielding line 41 away from the second electrode plate 43 of the storage capacitor, and a third initial signal line 45 is provided at a side of the second electrode plate 43 of the storage capacitor away from the first shielding line 41. The second shielding line 46 and the third initial signal line 45 may be in a structure of a bending line extending in the first direction X. Other structures in FIG. 38B are similar to those in FIG. 28B and will not be described in detail here. FIG. 39A is a schematic diagram of a planar structure after a second semiconductor layer is formed in the pixel driving circuit, and FIG. 39B is a schematic diagram of a planar structure of the second semiconductor layer in the pixel driving circuit; as shown in FIG. 39B, the second semiconductor layer may include an active layer 21 of the first transistor T1 and an active layer 22 of the second transistor T2, the first region 21-1 of the active layer of the first transistor T1 and the second region 22-2 of the active layer of the second transistor T2 may be independently disposed, and the second region 21-2 of the active layer 21 of the first transistor T1 and the first region 22-1 of the active layer 22 of the second transistor T2 are connected to each other. The active layer 21 of the first transistor T1 and the active layer 22 of the second transistor T2 may be an integrally formed structure. In the second direction Y, the active layer 21 of the first transistor T1 and the active layer 22 of the second transistor T2 are arranged sequentially, and the active layer 21 of the first transistor T1 and the active layer 22 of the second transistor T2 may be in an “I” shape. In an exemplary implementation, the first shielding line 41 is configured as a shielding layer of the first transistor T1 to shield the channel of the first transistor T1, and the second shielding line 46 is configured as a shielding layer of the second transistor T2 to shield the channel of the second transistor T2, thereby ensuring electrical performances of a first oxide transistor T1 and a second oxide transistor T2. In an exemplary embodiment, signals of the first shielding line 41 and the control electrode 53 of the first transistor TI formed subsequently may be the same, that is, the first shielding line 41 is connected in parallel with the control electrode 53 of the first transistor T1 formed subsequently, and both are connected with a same signal source, so that the first shielding line 41 may serve as a bottom gate electrode (i.e., a bottom control electrode) of the first transistor T1 to form the first transistor T1 with a double gate structure; signals of the second shielding line 46 and the control electrode 54 of the second transistor T2 formed subsequently may be the same, that is, the second shielding line 46 and the control electrode 54 of the second transistor T2 formed subsequently are connected in parallel, and both are connected with a same signal source, so that the second shielding line 42 may serve as a bottom gate electrode (i.e., a bottom control electrode) of the second transistor T2 to form the second transistor T2 with a double gate structure.

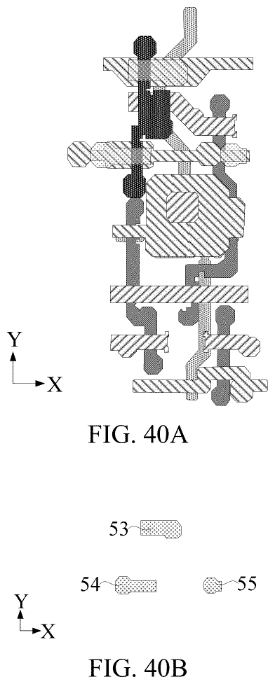

FIG. 40A is a schematic diagram of a planar structure after a third conductive layer is formed in the pixel driving circuit, and FIG. 40B is a schematic diagram of a planar structure of the third conductive layer in the pixel driving circuit; as shown in FIG. 40B, the third conductive layer may include a control electrode 53 of the first transistor T1, a control electrode 54 of the second transistor T2, and a transfer connection electrode 55. In the second direction Y, the control electrode 54 of the second transistor T2 and the transfer connection electrode 55 are positioned at a side of the control electrode 53 of the first transistor T1, and in the first direction X, the control electrode 54 of the second transistor T2 and the transfer connection electrode 55 are arranged sequentially along the first direction X.

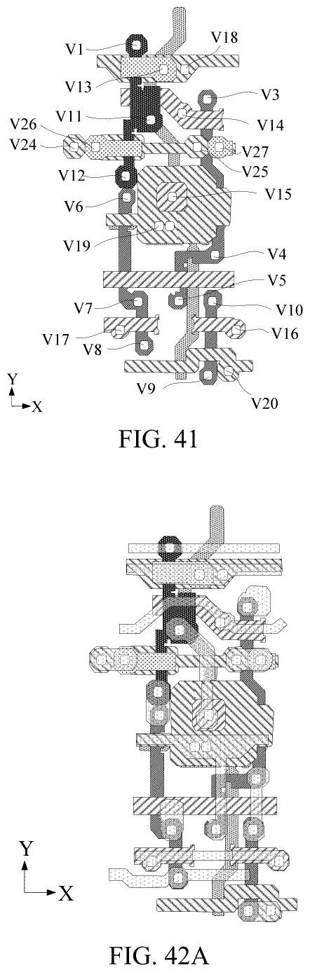

FIG. 41 is a schematic diagram of a planar structure in which a pattern of a sixth insulating layer is formed in the pixel driving circuit; FIG. 41 differs from FIG. 31 in that the second via V2 is not provided, and the sixth and fifth insulating layers in the first via V1 are etched away to expose the active layer of the first transistor T1; the sixth insulating layer, the fifth insulating layer, and the fourth insulating layer in the eighteenth via V18 are etched away to expose a surface of the second shielding line 46; the sixth insulating layer, the fifth insulating layer and the fourth insulating layer in the twentieth via V20 are etched away to expose a surface of the third initial signal line 45; a twenty-fourth via V24 to a twenty-seventh via V27 are added, and the sixth insulating layer, the fifth insulating layer and the fourth insulating layer in the twenty-fourth via V24 are etched away to expose a surface of the first shielding line 41; the sixth insulating layer, the fifth insulating layer and the fourth insulating layer in the twenty-fifth via V25 are etched away to expose a surface of the first shielding line 41; the sixth insulating layer in the twenty-sixth via V26 is etched away to expose a surface of the control electrode 54 of the second transistor T2; the sixth insulating layer in the twenty-seventh via V27 is etched away to expose a surface of the transfer connection electrode 55; other vias in FIG. 41 are similar to those in FIG. 31 and will not be described in detail here.

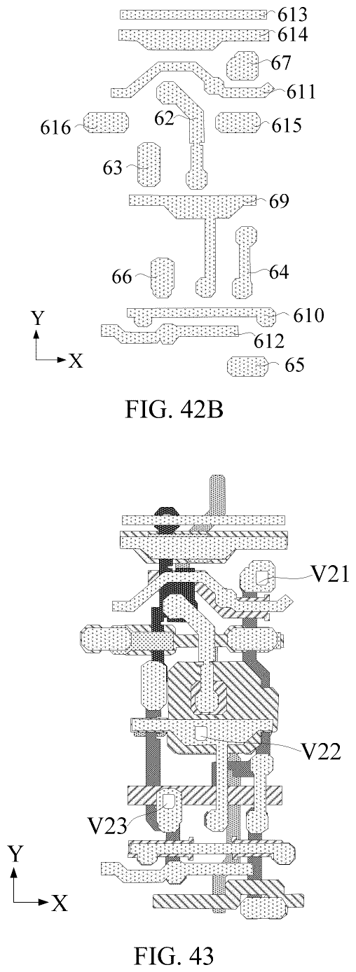

FIG. 42A is a schematic diagram of a planar structure after a first source-drain metal layer is formed in the pixel driving circuit, and FIG. 42B is a schematic diagram of a planar structure of the first source-drain metal layer in the pixel driving circuit; FIG. 42B differs from FIG. 32B in that the first transfer connection electrode 61 and the eighth transfer connection electrode 68 are not provided and a first initial signal line 613, a fourteenth connection electrode 614, a fifteenth connection electrode 615 and a sixteenth connection electrode 616 are added. The third connection electrode 63 is arranged to be electrically connected to the first region of the active layer of the sixth transistor T6 and the second region of the active layer of the second transistor T2 through the sixth via V6 and the twelfth via V12, respectively, the first initial signal line 613 is arranged to be electrically connected to the first region of the active layer of the first transistor T1 through the first via V1, the fourteenth connection electrode 614 is arranged to be electrically connected to the control electrode 53 of the first transistor T1 and the second shielding line 46 through the thirteenth via V13 and the eighteenth via V18, respectively, the fifteenth connection electrode 615 is arranged to be electrically connected with the first shielding line 41 and the control electrode 54 of the second transistor T2 through the twenty-fourth via V24 and the twenty-sixth via V26, respectively, and the sixteenth connection electrode 616 is arranged to be electrically connected with the first shielding line 41 and the transfer connection electrode 55 through the twenty-fifth via V25 and the twenty-seventh V27, respectively. Other vias in FIG. 42B are similar to those in FIG. 32B and will not be described in detail herein.

FIG. 43 is a schematic diagram of a planar structure in which patterns of a seventh insulating layer and a first planarization layer are formed in the pixel driving circuit; the twenty-first via 21 to the twenty-third via V23 in FIG. 43 are similar to those in FIG. 33 and will not be described in detail herein.

FIG. 44A is a schematic diagram of a planar structure after a second source-drain metal layer is formed in the pixel driving circuit, and FIG. 44B is a schematic diagram of a planar structure of the second source-drain metal layer in the pixel driving circuit. FIG. 44B differs from FIG. 34B in that the positions of the data line 73 and the third power supply connection line 72 are interchanged in the first direction X, and the position of the anode connection electrode 74 is provided at a side of the third power supply connection line 72 away from the power supply connection line 71. Other structures in FIG. 44B are similar to those in FIG. 34B and will not be described in detail here.

In an exemplary embodiment, the circuit schematic diagram shown in FIG. 23 differs from the circuit schematic diagram shown in FIG. 4 in that the first transistor T1 and the seventh transistor T7 may share one scan signal line.

In an exemplary embodiment, in a case where the pixel driving circuit in FIG. 23 is applied to the structure shown in FIGS. 8 and 11, the first initial signal line Vinit1 and the second initial signal line Vinit2 may be electrically connected to two of three initial signal supply lines Vinit; in a case where the pixel driving circuit in FIG. 23 is applied to a structure shown in FIG. 13, the first initial signal line Vinit1 and the second initial signal line Vinit2 may be electrically connected to two initial signal supply lines Vinit respectively. In a case where the pixel driving circuit shown in FIGS. 22a and 22b is applied to structures shown in FIGS. 8 and 11, the first initial signal line Vinit1, the second initial signal line Vinit2, and the third initial signal line Vinit3 may be electrically connected to three initial signal supply lines Vinit, respectively.

In an exemplary embodiment, as shown in FIG. 45, a schematic diagram of a structure of a pixel driving circuit located in the display region AA shown in FIG. 23 is shown. Included in the structure shown in FIG. 45 are 2 rows and 6 columns of pixel driving circuits shown in FIG. 23 (i.e., FIG. 45 shows pixel driving circuits in 2 rows and 6 columns of sub-pixels), herein, S1, S2, S4, S5, DL (data line), EML (light emitting control line), Vinit1 (initial signal line), Vinit2 (initial signal line) in FIG. 45 can be electrically connected to S1, S2, S4, S5, DL (i.e., the above-described data line D311), EML, Vinit1, Vinit2 in FIG. 23, respectively, and the scan signal line S1 of the first transistor T1 and the scan signal line S2 of the seventh transistor T7 may be one scan signal line; the scan signal line S5 of the second transistor T2 and the scan signal line S4 of the fourth transistor T4 may be one scan signal line.

In an exemplary embodiment, as shown in FIG. 45, the scan signal lines S1, S2, S4, S5 and the first and second initial signal lines Vinit1 and Vinit2 may be located in the first source-drain metal layer, and the data line DL and the third power supply connection line 72 (electrically connected with the second power supply line VDD to supply a voltage signal of the second power supply line VDD to the pixel driving circuit) may be located in the second source-drain metal layer.

In an exemplary embodiment, in FIG. 45, L121 are the above-mentioned first power supply connection lines, L122 are the above-mentioned second power supply connection lines, the first power supply connection lines L121 may be located in the first source-drain metal layer, the second power supply connection lines L122 may be located in the second source-drain metal layer, and the first power supply connection lines L121 and the second power supply connection lines L122 may be electrically connected to each other in the display region AA to form a mesh shape, as shown in FIG. 23. The first power supply connection lines L121 and the second power supply connection lines L122 may be electrically connected at a first connection position Q1, a second connection position Q2, a third connection position Q3 and a fourth connection position Q4, for example, the first power supply connection lines L121 and the second power supply connection lines L122 can be electrically connected through vias at the first connection position Q1 to the fourth connection position Q4.

In an exemplary embodiment, as shown in FIG. 45, in the second direction Y, a pitch H1 between two adjacent first power supply connection lines L121 is consistent with a width H2 of one sub-pixel row along the second direction Y; in the first direction X, a pitch H3 between two adjacent second power supply connection lines L122 is consistent with a width of at least one sub-pixel column along the first direction X. For example, the pitch H3 between two adjacent second power supply connection lines L122 may be consistent with a width H4 of three sub-pixel columns in the first direction X. In a structure shown in FIG. 45, a plurality of sub-pixels may form a plurality of pixels arranged in an array, one pixel may include three sub-pixels, for example, one pixel may include three sub-pixels arranged in the first direction X, a width of one pixel column along the first direction X may be consistent with a width of the three sub-pixel columns along the first direction X, and a size of one pixel row along the second direction Y may be consistent with a size of one sub-pixel row along the second direction Y.

The present disclosure further provides a display apparatus, including the display substrate according to any of the aforementioned embodiments. The display apparatus may be any product or component with a display function, such as a mobile phone, a tablet computer, a television, a display, a laptop computer, a digital photo frame, or a navigator.

In the base substrate and the display apparatus according to embodiments of the present disclosure, a power supply auxiliary line connected to the first power supply line is provided in a corner region of a bezel region in the display substrate, and a plurality of power supply connection lines connected to the power supply auxiliary lines are provided in a corner region of the bezel region and a corner region of the display region, so that signals of the first power supply line can be provided to the corner region of the display region through the plurality of power supply connection lines and the power supply auxiliary lines, thereby improving the display uniformity of the display substrate.

The drawings of the embodiments of the present disclosure only involve structures involved in the embodiments of the present disclosure, and other structures may refer to a general design.

The embodiments of the present disclosure, that is, features in the embodiments, may be combined with each other to obtain a new embodiment in a situation of no conflicts.

Although the embodiments disclosed in embodiments of the present disclosure are described as above, the described contents are only the embodiments for facilitating understanding of the present disclosure, which are not intended to limit the present disclosure. Any of those skilled in the art of the present disclosure can make any modifications and variations in the implementation mode and details without departing from the spirit and scope of the present disclosure. However, the protection scope of the present disclosure should be subject to the scope defined by the appended claims.

1. A display substrate, comprising:
a display region and a bezel region located around the display region, wherein the display region comprises at least one corner region, the bezel region comprises at least one corner region, and the at least one corner region of the display region corresponds to the at least one corner region of the bezel region;
a power supply auxiliary line, located in at least one corner region of the bezel region and arranged to be electrically connected with a first power supply line; and
a plurality of power supply connection lines, wherein at least a portion of the power supply connection lines of the plurality of power supply connection lines is arranged to be electrically connected with the power supply auxiliary line, and extends from the corner region of the bezel region where the power supply auxiliary line is located to a corresponding corner region of the display region.

2. The display substrate according to claim 1, wherein the plurality of power supply connection lines comprises a plurality of first power supply connection lines and a plurality of second power supply connection lines, an extension direction of the plurality of first power supply connection lines is intersected with an extension direction of the plurality of second power supply connection lines, and at least a portion of the first power supply connection lines of the plurality of first power supply connection lines is electrically connected with at least a portion of the second power supply connection lines of the plurality of second power supply connection lines.

3. The display substrate according to claim 2, wherein: the at least a portion of the first power supply connection lines is located in at least one corner region of the bezel region and extends along a first direction;
the at least a portion of the second power supply connection lines extends along a second direction and extends from at least one corner region of the bezel region where the power supply auxiliary line is located to at least one corresponding corner region of the display region; and
the power supply auxiliary line is respectively electrically connected with the at least a portion of the first power supply connection lines and the at least a portion of the second power supply connection lines, and the power supply auxiliary line, at least a portion of the first power supply line and at least a portion of a second power supply line form a mesh structure in at least one corner region of the bezel region where the power supply auxiliary line is located.

4. The display substrate according to claim 1, wherein a width of the power supply auxiliary line gradually decreases from an end connected to the first power supply line to an end away from the first power supply line.

5. The display substrate according to claim 4, wherein: in a direction perpendicular to a plane where the display substrate is located, the display substrate comprises a base substrate and a first conductive layer, a second conductive layer, a first source-drain metal layer and a second source-drain metal layer stacked on the base substrate sequentially; the power supply auxiliary line, the first power supply line, the plurality of first power supply connection lines and the plurality of second power supply connection lines are located in the second source-drain metal layer, and the first power supply line is located at a side of the power supply auxiliary line away from the display region.

6. The display substrate according to claim 5, further comprising a plurality of signal connection lines located in the bezel region, a plurality of signal lines located in the display region and a bonding region located at a side of the display region, wherein:
one end of at least a portion of the signal connection lines is arranged to be electrically connected with the plurality of signal lines respectively, and the other end of the at least a portion of the signal connection lines is arranged to be connected with the bonding region;
the at least a portion of the signal connection lines is located in at least one corner region of the bezel region and is arranged in the first conductive layer and the second conductive layer; and
orthographic projections of the at least a portion of the signal connection lines on the base substrate are at least partially overlapped with an orthographic projection of the power supply auxiliary line on the base substrate.

7. The display substrate according to claim 6, wherein orthographic projections of the signal connection lines located in the bezel region on the base substrate are within a range of the orthographic projection of the power supply auxiliary line on the base substrate.

8. The display substrate according to claim 5, further comprising at least one initial signal supply line located in the second source-drain metal layer, wherein
the at least one initial signal supply line is located in the bezel region, and in a corner region of the bezel region where the power supply auxiliary line is located, the at least one initial signal supply line is located at a side of the power supply auxiliary line away from the display region.

9. The display substrate according to claim 8, further comprising a plurality of gate driving circuits, wherein the plurality of gate driving circuits and the at least one initial signal supply line are located in different film layers;
at least a portion of the gate driving circuits is located in at least one corner region of the bezel region and between the power supply auxiliary line and the first power supply line; and
the at least one initial signal supply line is located between the plurality of gate driving circuits and the power supply auxiliary line in the corner region of the bezel region where the power supply auxiliary line is located, or an orthographic projection of the at least one initial signal supply line on the base substrate is at least partially overlapped with orthographic projections of the plurality of gate driving circuits on the base substrate.

10. The display substrate according to claim 2, wherein the power supply auxiliary line is electrically connected to the at least a portion of the first power supply connection lines;
the at least a portion of the first power supply connection lines extends along a first direction and extends from at least one corner region of the bezel region where the power supply auxiliary line is located to at least one corresponding corner region of the display region;
the at least a portion of the second power supply connection lines is located in the display region and extends in a second direction, and the at least a portion of the first power supply connection lines and the at least a portion of the second power supply connection lines form a mesh structure in at least one corner region of the display region.

11. The display substrate according to claim 10, wherein: in a direction perpendicular to a plane where the display substrate is located, the display substrate comprises a base substrate and a first conductive layer, a second conductive layer, a first source-drain metal layer, and a second source-drain metal layer stacked on the base substrate sequentially; the plurality of first power supply connection lines are located in the first source-drain metal layer, the plurality of second power supply connection lines are located in the second source-drain metal layer, and the first power supply line is located at a side of the power supply auxiliary line away from the display region; and the first power supply line is of a single-layer structure located in the first source-drain metal layer or the second source-drain metal layer, or the first power supply line is of a double-layer structure located in the first source-drain metal layer and the second source-drain metal layer.

12. The display substrate according to claim 11, further comprising at least one initial signal supply line, wherein:
the at least one initial signal supply line is located in the bezel region, and in the corner region of the bezel region where the power supply auxiliary line is located, the at least one initial signal supply line is located between the power supply auxiliary line and the display region.

13. The display substrate according to claim 12, further comprising a plurality of gate driving circuits located in the first conductive layer, the second conductive layer, and the first source-drain metal layer, wherein at least a portion of the gate driving circuits is located in at least one corner region of the bezel region and at a side of the power supply auxiliary line away from the at least one initial signal supply line.

14. The display substrate according to claim 13, wherein: the at least one initial signal supply line and the power supply auxiliary line are located in one of the first source-drain metal layer and the second source-drain metal layer; or the at least one initial signal supply line and the power supply auxiliary line are of a double-layer structure located in the first source-drain metal layer and the second source-drain metal layer; or one of the at least one initial signal supply line and the power supply auxiliary line is located in one of the first source-drain metal layer and the second source-drain metal layer, and the other is of a double-layer structure located in the first source-drain metal layer and the second source-drain metal layer; and
the at least one initial signal supply line and the power supply auxiliary line are located between the plurality of gate driving circuits and the display region in the corner region of the bezel region where the power supply auxiliary line is located.

15. The display substrate according to claim 13, wherein: the at least one initial signal supply line and the power supply auxiliary line are of a single-layer structure located in the second source-drain metal layer; and
orthographic projections of the at least one initial signal supply line and the power supply auxiliary line on the base substrate are at least partially overlapped with orthographic projections of the plurality of gate driving circuits on the base substrate.

16. The display substrate according to claim 14, further comprising a plurality of first transfer connection electrodes disposed on at least one film of the first conductive layer and the second conductive layer, wherein
the plurality of first transfer connection electrodes are located in at least one corner region of the bezel region where the power supply auxiliary line is located, and are arranged along an extension direction of the power supply auxiliary line, one end of the plurality of first transfer connection electrodes is electrically connected with the power supply auxiliary line, and the other end of the plurality of first transfer connection electrodes is electrically connected with the plurality of first power supply connection lines respectively.

17. The display substrate according to claim 14, further comprising a third source-drain metal layer, wherein at least one of the at least one initial signal supply line and the power supply auxiliary line is located in the third source-drain metal layer.

18. The display substrate according to claim 10, wherein the at least a portion of the first power supply connection lines extends in the first direction to a non-corner region of the display region, and the at least a portion of the second power supply connection lines extends in the second direction to the non-corner region of the display region; or
the at least a portion of the first power supply connection lines penetrates through the display region in the first direction and extends from one of corner regions of the display region to a corner region on an opposite side of the display region along the first direction; the at least a portion of the second power supply connection lines penetrates through the display region in the second direction and extends from one of corner regions of the display region to a corner region on an opposite side of the display region along the second direction.

19. The display substrate according to claim 8, wherein a boundary of at least one corner region of the display region and at least one corresponding corner region of the bezel region are all in a shape of an arc, in at least one corner region of the bezel region, the power supply auxiliary line, the at least one initial signal supply line and the first power supply line are all in a shape of an arc consistent with a shape of a corner region of the bezel region where the power supply auxiliary line, the at least one initial signal supply line and the first power supply line are located, respectively, the power supply auxiliary line and the first power supply line are an integrally formed structure.

20-24. (canceled)

25. A display apparatus, comprising the display substrate according to claim 1.
